(19) United States
(12) Patent Application Publication
(10) Pub. No.: US 2012/0213615 A1
(43) Pub. Date: Aug. 23, 2012

(54) TARGET OBJECT TRANSFER METHOD AND TARGET OBJECT PROCESSING APPARATUS

(75) Inventor: Hiromitsu Sakaue, Nirasaki-shi (JP)

(73) Assignee: TOKYO ELECTRON LIMITED, TOKYO (JP)

(21) Appl. No.: 13/499,143

(22) PCT Filed: Sep. 22, 2010
(86) PCT No.: PCT/JP10/66383

§ 371 Date: Mar. 29, 2012

(30) Foreign Application Priority Data
Sep. 30, 2009 (JP) 2009-228856

(51) Int. Cl. H01L 21/677

(52) U.S. Cl. 414/217; 414/805

(57) ABSTRACT

A target object transfer method overcomes the limits to productivity encounted even if a process time of various processes is shortened. In the transfer method, each of the load-lock chambers is configured to store target objects. First objects not having been processed are carried out into the load-lock chambers, and processed second objects are carried out at the same time from a plurality of processing chambers to a transfer chamber using a transfer device. The processed second objects are carried at the same time into the load-lock chambers from the transfer chamber, and the first objects not having been processed are carried out at the same time to the transfer chamber from the load-lock chambers using the transfer device, and the first object not having been processed are carried into the processing chambers at the same time from the transfer chamber.

### FIELD OF THE INVENTION

The present invention relates to a target object transfer method and a target object processing apparatus.

### BACKGROUND OF THE INVENTION

In a manufacturing process of an electronic device, a target object is used, and various processes such as film formation, etching and the like are performed on the target object. For example, in a manufacturing process of a semiconductor integrated circuit device apparatus, a semiconductor wafer is used as the target object, and various processes such as film formation, etching and the like are performed on the semiconductor wafer. In general, such processes are carried out in separate processing apparatuses. For example, a film forming process is performed in a film forming apparatus having a film forming chamber, while an etching process is performed in an etching processing apparatus having an etching processing chamber.

Recently, in order to achieve a processing integration and reduce the foot print that is caused by an increase in the number of the processing apparatus, there has been widely used a multi chamber (cluster tool) type processing apparatus for processing a processing target object in which a plurality of processing chambers is disposed around a transfer chamber. A typical example of the multi chamber type processing apparatus for processing a processing target object is described in, e.g., Japanese Patent Application Publication No. 2005-64509.

Further, Japanese Patent Application Publication Nos. 2005-64509 and 2004-282002 describe a transfer device using a multi-joint robot that is used for transferring the target object between the transfer chamber and the processing chambers.

Meanwhile, in various processes such as film formation, etching and the like, extensive efforts have been devoted to reduce the processing time in order to improve the productivity.

However, once the reduction in the processing times of the respective processes is achieved, a rate control factor for the time required for overall processing of a processing target object in the multi chamber type apparatus is changed from the process rate control to the transfer rate control. For that reason, even if each of the processing times is substantially reduced, the improvement in the productivity is limited.

### SUMMARY OF THE INVENTION

In view of the above, the present invention provides a target object transfer method and a target object transfer apparatus capable of solving the problem in which the increase in the productivity is limited even if the processing time is shortened.

In accordance with a first aspect of the invention, there is provided a target object transfer method for a target object processing apparatus, which includes a transfer chamber in which a transfer device for transferring target objects is provided, processing chambers disposed around the transfer chamber to process the target objects, and load-lock chambers disposed around the transfer chamber to convert an environment around the target objects to an environment inside the transfer chamber, each load-lock chamber being configured to accommodate therein parts of the target objects, the method including: (0) loading unprocessed first target objects into the load-lock chambers; (1) simultaneously unloading processed second target objects into the transfer chamber from the processing chambers by using the transfer device; (2) simultaneously unloading the processed second target objects into the load-lock chambers from the transfer chamber by using the transfer device; (3) simultaneously loading the unprocessed first target objects into the transfer chamber from the load-lock chambers by using the transfer device; (4) simultaneously loading the unprocessed first target objects into the processing chambers from the transfer chamber by using the transfer device; (5) unloading the processed second target objects from the load-lock chambers.

In accordance with a second aspect of the invention, there is provided a target object transfer method for a target object processing apparatus, which includes a transfer chamber in which a transfer device for transferring target objects is provided, processing chambers disposed around the transfer chamber to process the target objects, and load-lock chambers disposed around the transfer chamber to convert an environment around the target objects to an environment inside the transfer chamber, each load-lock chamber being configured to accommodate therein parts of the target objects, the method including: (0) loading unprocessed first target objects into the load-lock chambers; (1) simultaneously unloading processed second target objects into the transfer chamber from a part of the processing chambers by using the transfer device; (2) simultaneously unloading the processed second target objects into the load-lock chambers from the transfer chamber by using the transfer device; (3) simultaneously unloading processed third target objects into the transfer chamber from another part of the processing chambers other than the part of the processing chambers by using the transfer device; (4) simultaneously loading the processed third target objects into the transfer chamber from said another part of the processing chambers by using the transfer device; (5) simultaneously loading the unprocessed first target objects into the transfer chamber from the load-lock chambers by using the transfer device; (6) simultaneously loading the unprocessed first target objects into the transfer chamber from the load-lock chambers by using the transfer device; and (7) unloading the processed second target objects from the load-lock chambers.

In accordance with a third aspect of the invention, there is provided a target object processing apparatus including: a transfer chamber in which a transfer device for transferring target objects is provided; processing chambers, disposed around the transfer chamber, for processing the target objects; and load-lock chambers, disposed around the transfer chamber, for converting an environment around the target objects to an environment inside the transfer chamber, wherein each of the load-lock chambers is configured to accommodate parts of the target objects, and wherein the transfer device is configured to simultaneously transfer the target objects between the processing chambers and the transfer chamber, between the transfer chamber and the load-lock chambers, and between a first part of the processing chambers and a second part of the processing chambers other than the first part of the processing chambers.

In accordance with a fourth aspect of the invention, there is provided a target object transfer method for a target object processing apparatus, which includes a transfer chamber in which a transfer device for transferring target objects is provided, processing chambers disposed around the transfer chamber to process the target objects, and load-lock chambers disposed around the transfer chamber to convert an environment around the target objects to an environment inside the transfer chamber, the method including: (0) loading unprocessed first target objects into the load-lock chambers; (1) simultaneously transferring at least one of processed second target objects and at least one of the unprocessed first target objects into the transfer chamber from at least one of the processing chambers and at least one of the load-lock chambers by using the transfer device; (2) simultaneously transferring said at least one of the processed second target objects and said at least one of the unprocessed first target objects from the transfer chamber into said at least one of the load-lock chambers and said at least one of the processing chambers by using the transfer device; and (3) unloading said at least one of the processed second target objects from said at least one of the load-lock chambers.

In accordance with a fifth aspect of the invention, there is provided a target object processing apparatus including: a transfer chamber in which a transfer device for transferring target objects is provided; processing chambers, disposed around the transfer chamber, for processing the target objects; and load-lock chambers, disposed around the transfer chamber, for converting an environment around the target objects to an environment inside the transfer chamber, wherein the transfer device is configured to simultaneously transferring the target objects between at least one of the processing chambers and at least one of the load-lock chambers.

In accordance with a sixth aspect of the invention, there is provided a target object transfer method for a target object processing apparatus, which includes a transfer chamber in which a transfer device for transferring target objects is provided, processing chambers disposed around the transfer chamber to process the target objects, and load-lock chambers disposed around the transfer chamber to convert an environment around the target objects to an environment inside the transfer chamber, each of the load-lock chambers and its corresponding one of the processing chambers being arranged linearly via the transfer chamber, the method including: (0) loading unprocessed first target objects into the load-lock chambers; (1) simultaneously transferring one of processed second target objects and one of the unprocessed first target objects into the the transfer chamber from one of the processing chambers and one of the load-lock chambers by using the transfer device, said one of the load-lock chambers and said one of the processing chambers being disposed linearly via the transfer chamber; (2) simultaneously transferring said one of the processed second target objects and said one of the unprocessed target objects into said one of the load-lock chambers and said one of the processing chambers from the transfer chamber by using the transfer device; and (3) unloading the processed second transfer target objects from the load-lock chambers.

In accordance with a seventh aspect of the invention, there is provided a target object processing apparatus including: a transfer chamber in which a transfer device for transferring a target object is provided; processing chambers, disposed around the transfer chamber, for processing the target object; and load-lock chambers, disposed around the transfer chamber, for converting an environment around the target object to an atmosphere in the transfer chamber, wherein each of the load-lock chambers and its corresponding one of the processing chambers are arranged linearly via the transfer chamber, and wherein the transfer device is configured to simultaneously transferring target objects between one of the processing chambers and at least one of the load-lock chambers, said one of the load-lock chambers and said one of the processing chambers being disposed linearly via the transfer chamber.

### BRIEF DESCRIPTION OF THE DRAWINGS

FIG. 1 is a top view showing an example of a target object processing apparatus capable of performing a target object transfer method in accordance with a first embodiment of the present invention.

FIG. 2 is a cross sectional view showing an example of a load-lock chamber.

FIG. 3A is a top view showing an example of the target object transfer method in accordance with the first embodiment of the present invention.

FIG. 3B is a top view showing an example of the target object transfer method in accordance with the first embodiment of the present invention.

FIG. 3C is a top view showing an example of the target object transfer method in accordance with the first embodiment of the present invention.

FIG. 3D is a top view showing an example of the target object transfer method in accordance with the first embodiment of the present invention.

FIG. 3E is a top view showing an example of the target object transfer method in accordance with the first embodiment of the present invention.

FIG. 3F is a top view showing an example of the target object transfer method in accordance with the first embodiment of the present invention.

FIG. 4 is a timing diagram of an example of the target object transfer method in accordance with the first embodiment of the present invention.

FIG. 5A is a top view showing a target object transfer method in accordance with a reference example.

FIG. 5B is a top view showing the target object transfer method in accordance with the reference example.

FIG. 5C is a top view showing the target object transfer method in accordance with the reference example.

FIG. 5D is a top view showing the target object transfer method in accordance with the reference example.

FIG. 5E is a top view showing the target object transfer method in accordance with the reference example.

FIG. 5F is a top view showing the target object transfer method in accordance with the reference example.

FIG. 6 is a timing diagram of the reference examples shown in FIGS. 5A to 5F.

FIGS. 7A to 7D are top views showing an example of a transfer device used in a second example of the target object transfer method in accordance with the first embodiment of the present invention.

FIG. 8A is a top view showing the second example of the target object transfer method in accordance with the first embodiment of the present invention.

FIG. 8B is a top view showing the second example of the target object transfer method in accordance with the first embodiment of the present invention.

FIG. 8C is a top view showing the second example of the target object transfer method in accordance with the first embodiment of the present invention.

FIG. 8D is a top view showing the second example of the target object transfer method in accordance with the first embodiment of the present invention.

FIG. 8E is a top view showing the second example of the target object transfer method in accordance with the first embodiment of the present invention.

FIG. 8F is a top view showing the second example of the target object transfer method in accordance with the first embodiment of the present invention.

FIG. 8G is a top view showing the second example of the target object transfer method in accordance with the first embodiment of the present invention.

FIG. 8H is a top view showing the second example of the target object transfer method in accordance with the first embodiment of the present invention.

FIG. 9 is a timing diagram of the second example of the target object transfer method in accordance with the first embodiment of the present invention.

FIG. 10 is a timing diagram for explaining advantages of the transfer device shown in FIG. 7.

FIG. 11 is a cross sectional view showing an example of a load-lock chamber used in a third example of the target object transfer method in accordance with the first embodiment of the present invention.

FIG. 12A is a top view showing the third example of the target object transfer method in accordance with the first embodiment of the present invention.

FIG. 12B is a top view showing the third example of the target object transfer method in accordance with the first embodiment of the present invention.

FIG. 12C is a top view showing the third example of the target object transfer method in accordance with the first embodiment of the present invention.

FIG. 12D is a top view showing the third example of the target object transfer method in accordance with the first embodiment of the present invention.

FIG. 12E is a top view showing the third example of the target object transfer method in accordance with the first embodiment of the present invention.

FIG. 13 is a timing diagram of a third example of the target object transfer method in accordance with the first embodiment of the present invention.

FIG. 14 is a top view showing an example of a target object processing apparatus capable of performing the third example of the target object transfer method in accordance with the first embodiment of the present invention.

FIG. 15A is a top view showing an example of a target object processing apparatus capable of performing a target object transfer method in accordance with a second embodiment of the present invention.

FIG. 15B is a top view showing an example of the target object processing apparatus capable of performing the target object transfer method in accordance with a second embodiment of the present invention.

FIG. 15C is a top view showing an example of the target object processing apparatus capable of performing the target object transfer method in accordance with a second embodiment of the present invention.

FIG. 16 is a cross sectional view showing an example of a load-lock chamber which can be used in the target object transfer method in accordance with the second embodiment of the present invention.

FIG. 17A is a top view showing a first example of the target object transfer method in accordance with the second embodiment of the present invention.

FIG. 17B is a top view showing the first example of the target object transfer method in accordance with the second embodiment of the present invention.

FIG. 17C is a top view showing the first example of the target object transfer method in accordance with the second embodiment of the present invention.

FIG. 17D is a top view showing the first example of the target object transfer method in accordance with the second embodiment of the present invention.

FIG. 17E is a top view showing the first example of the target object transfer method in accordance with the second embodiment of the present invention.

FIG. 18 is a timing diagram of the first example of the target object transfer method in accordance with the second embodiment of the present invention.

FIG. 19 is a timing diagram of a second example of the target object transfer method in accordance with the second embodiment of the present invention.

FIG. 20 is a timing diagram of a third example of the target object transfer method in accordance with the second embodiment of the present invention.

### DETAILED DESCRIPTION OF THE EMBODIMENTS

Hereinafter, embodiments of the present invention will be described with reference to the accompanying drawings which form a part hereof. Further, like reference numerals will be given to like parts throughout all the drawings.

### First Embodiment

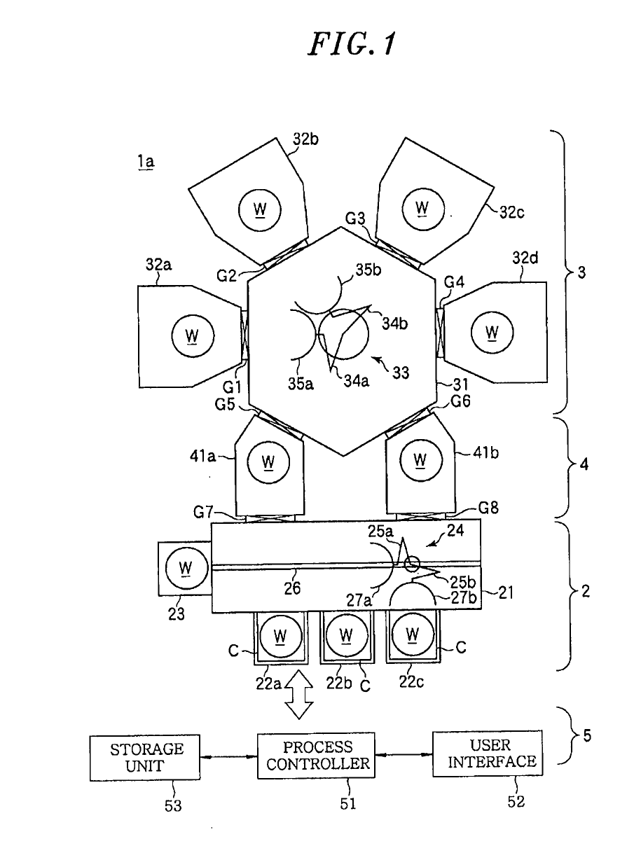

FIG. 1 is a top view schematically showing an example of a target object processing apparatus capable of performing a target object transfer method in accordance with a first embodiment of the present invention. In this example, a multi chamber (cluster tool) type semiconductor manufacturing apparatus using a semiconductor wafer as a processing target object is employed as an example of a target object processing apparatus.

As shown in FIG. 1, a semiconductor manufacturing apparatus 1a includes a loader module 2 for loading and unloading the semiconductor wafer W (hereinafter, referred to as wafer) by transferring it between the semiconductor manufacturing apparatus 1a and the outside, a processing unit 3 for processing the wafer W, a load-lock unit 4 for loading and unloading the wafer W transferred between the loader module 2 and the processing unit 3, and a control unit 5 for controlling the semiconductor manufacturing apparatus 1a.

The loader module 2 has a loader unit 21. The pressure inside the loader unit 21 can be controlled to the atmospheric pressure or close to the atmospheric pressure, e.g., a slight positive pressure with respect to the outside atmospheric pressure. In this example, the loader unit 21 is of a rectangular shape when seen from the top, the rectangular shape having longer sides and shorter sides perpendicular to the longer sides. The processing unit 3 is disposed to face one of the longer sides of the rectangle via the load-lock unit 4. One or more loading ports 22a to 22c, each for mounting a carrier C which is either accommodating wafers W therein or empty, are provided at the other one of the longer sides. In this example, three loading ports 22a to 22c are provided. The number of the loading ports 22 is not limited to three and can be varied. Each of the loading ports 22a to 22c is provided with a shutter (not shown). When the carrier C is mounted on one of the loading ports 22a to 22c, the shutter is opened so that the inner space of the carrier C and that of the loader unit 21 can communicate with each other while preventing intrusion of air from outside. An orienter 23 for aligning the direction of the wafers W unloaded from the carrier C is provided at a shorter side of the rectangle.

The processing unit 3 includes a transfer chamber 31 and a plurality of processing chambers 32 for processing the wafers W. In this example, a single transfer chamber 31 and four processing chambers 32a to 32d arranged around the transfer chamber 31 are provided. Each of the processing chambers 32a to 32d is configured as a vacuum chamber having an inner space that can be evacuated to a predetermined vacuum level, and a processing such as film formation, etching or the like can be performed therein. The processing chambers 32a to 32d are connected to the transfer chamber 31 through gate valves G1 to G4, respectively.

The load-lock unit 4 has a plurality of load-lock chambers 41. In this example, two load-lock chambers 41a and 41b are arranged around the single transfer chamber 31. Each of the load-lock chambers 41a and 41b is configured as a vacuum chamber having an inner space that can be evacuated to a predetermined vacuum level. The pressure in each of the load-lock chambers 41a and 41b can be changed between the predetermined vacuum level and the atmospheric pressure (or close to the atmospheric pressure), so that the environment around the wafer W can be equivalent to that inside the transfer chamber 31. The load-lock chambers 41a and 41b are connected to the transfer chamber 31 through gate valves G5 and G6 and also connected to the loader unit 21 through gate valves G7 and G8, respectively.

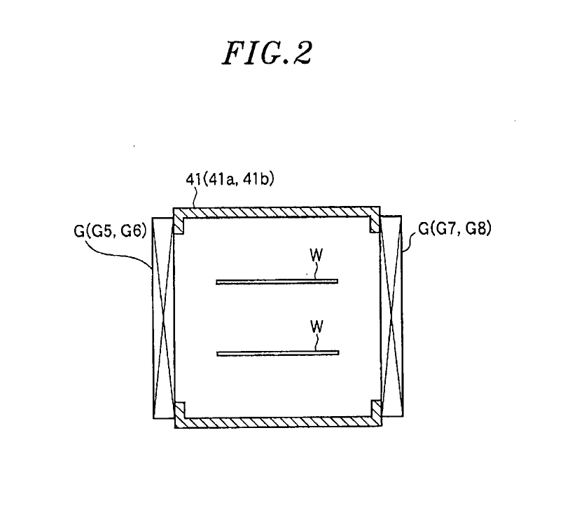

Besides, each of the load-lock chambers 41a and 41b can accommodate therein a plurality of wafers W. In order to accommodate a plurality of wafers W, each of the load-lock chambers 41 (41a and 41b) can have a structure in which two wafers W are arranged on top of one another respectively at an upper and a lower stage as shown in FIG. 2.

A loading/unloading device 24 is provided inside the loader unit 21. The loading/unloading device 24 performs loading and unloading of the wafers W as well as transferring them between the carrier C and the loader unit 21, between the loader unit 21 and the orienter 23, and between the loader unit 21 and the load-lock chambers 41a and 41b. The loading/unloading device 24 is configured to have a plurality of multi-joint arms 25 and travel on a rail 26 extending along the longer side direction of the loader unit 21. In this example, two multi-joint arms 25a and 25b are provided. The multi-joint arms 25a and 25b have hands 27a and 27b at leading ends thereof. In order to load a wafer W into the processing unit 3, the wafer W is unloaded from a carrier C by using the hand 27a or 27b and then loaded into the orienter 23. Next, the direction of the wafer W is adjusted in the orienter 23. Thereafter, the wafer W is unloaded from the orienter 23 by using the hand 27a or 27b and then loaded into the load-lock chamber 41a or 41b. When the wafer W is ready to be unloaded from the processing unit 3, the wafer W is unloaded from the load-lock chamber 41a or 41b by using the hand 27a or 27b and then loaded into the carrier C.

A transfer device 33 is provided inside the transfer chamber 31. The transfer device 33 performs loading and unloading of the wafers W as well as transferring them between the load-lock chambers 41a and 41b and the transfer chamber 31 and between the transfer chamber 31 and the processing chambers 32a to 32d. In this example, the transfer device 33 is disposed substantially at the center of the transfer chamber 31. The transfer device 33 has a plurality of transfer arms 34 capable of extending, contracting and rotating. In this example, the transfer device 33 has two transfer arms 34a and 34b. The transfer arms 34a and 34b have picks 35a and 35b at leading ends thereof. The wafer W held on the pick 35a or 35b is loaded and unloaded between the load-lock chambers 41a and 41b and the transfer chamber 31 and between the transfer chamber 31 and the processing chambers 32a to 32d.

In this example, the transfer device 33 is configured to simultaneously load and unload wafers W between the processing chambers 32a to 32d and the transfer chamber 31 and between the transfer chamber 31 and the load-lock chambers 41a to 41b.

The control unit 5 has a process controller 51, a user interface 52, and a storage unit 53. The process controller 51 has a microprocessor (computer). The user interface 52 has a keyboard through which an operator inputs commands to manage the semiconductor manufacturing apparatus la, a display for visually displaying an operation status of the semiconductor manufacturing apparatus 1a or the like. The storage unit 53 stores therein control programs for implementing various processes performed by the semiconductor manufacturing apparatus 1a under the control of the process controller 51, and recipes for executing processes in the semiconductor manufacturing apparatus 1a in accordance with various data and process conditions. The recipes are stored in a storage medium of the storage unit 53. The storage medium may be a computer readable storage medium, e.g., a hard disk, or a portable storage medium such as a CD-ROM, a DVD, a flash memory or the like. Alternatively, the recipes may be appropriately transmitted from another device via, e.g., a dedicated transmission line. A certain recipe is retrieved from the storage unit 53 under an instruction, e,g., inputted through the user interface 52 and executed by the process controller 51, so that a desired process is performed on the wafer W in the semiconductor manufacturing apparatus 1a under the control of the process controller 51.

Hereinafter, a first example of a target object transfer method in accordance with a first embodiment of the present invention will be described.

### First Embodiment

### FIRST EXAMPLE

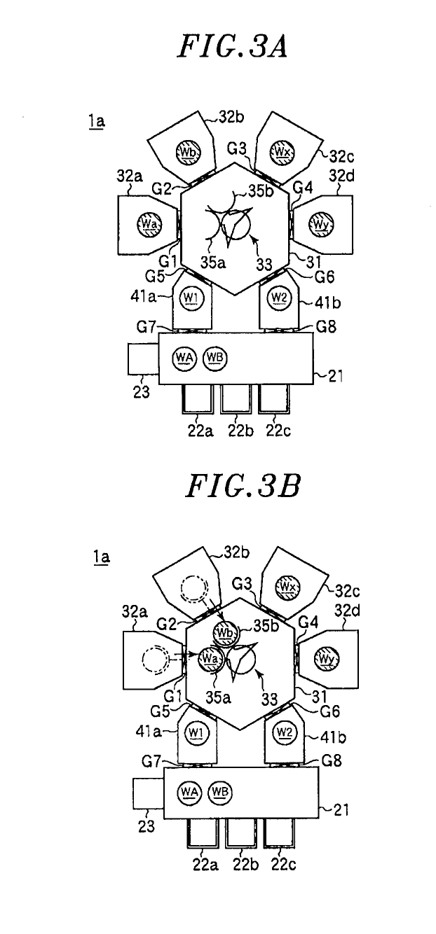

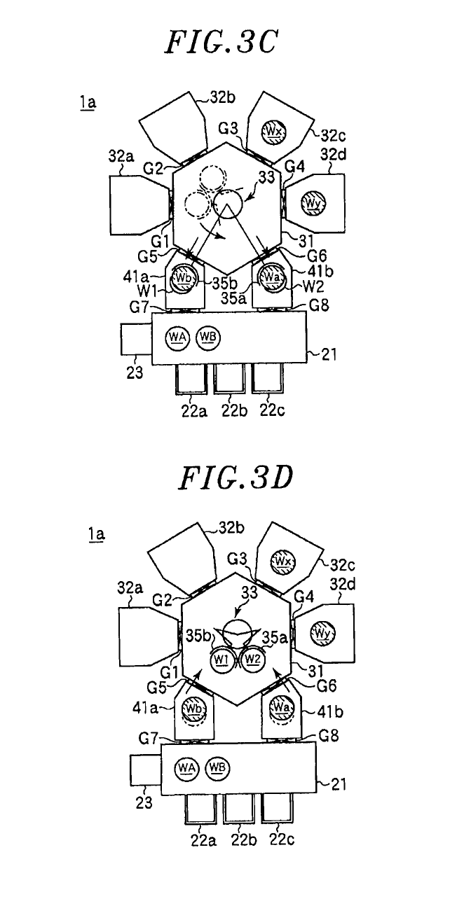

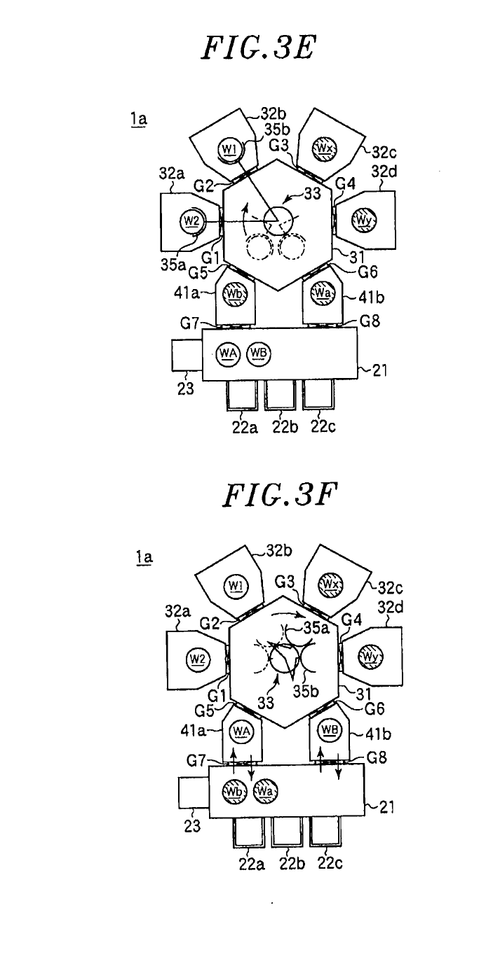

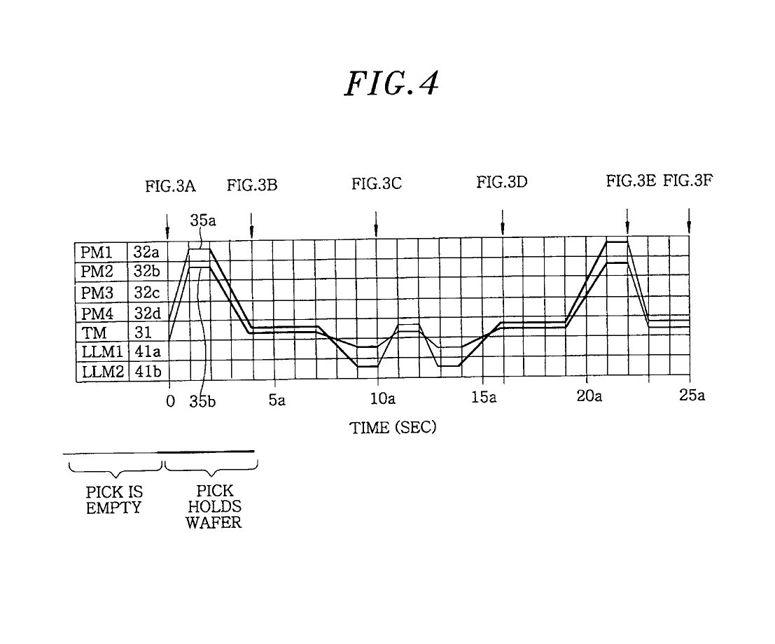

FIGS. 3A to 3F are top views showing a first example of the target object transfer method in accordance with the first embodiment of the present invention. FIG. 4 is a timing diagram of the first example. In the first example, the same processing is performed on four wafers W in the processing chambers 32a to 32d in parallel.

First, as shown in FIG. 3A and 4, unprocessed wafers W1 and W2 are loaded into the load-lock chambers 41a and 41b, respectively. At this time, the transfer device 33 is rotated such that the pick 35a of the transfer device 33 is positioned in front of the gate valve G1 to communicate with the processing chamber 32a and the pick 35b is positioned in front of the gate valve G2 to communicate with the processing chamber 32b. In the processing chamber 32a, the processing of a wafer Wa is completed. In the processing chamber 32b, the processing of a wafer Wb is completed.

Next, as shown in FIGS. 3B and 4, the processed wafers Wa and Wb are simultaneously unloaded from the processing chambers 32a and 32b and loaded into the transfer chamber 31 by the transfer device 33, respectively. In this example, the processed wafers Wa and Wb are held by the picks 35a and 35b, respectively. The time needed to reach this state from the state shown in FIG. 3A is about 4a sec.

The notation “a” denotes the time required until the wafer W is held by the picks 35a and 35b or the time required until the wafer W is released from the picks 35a and 35b. The unit thereof is “second”. The notation “a” is a parameter that is changed in accordance with types of the transfer arm.

In the example of this specification, the time required to extend, contract and rotate the transfer arms 34a and 34b is assumed as follows.

“state in which the wafer W is held by the pick 35”

time to extend the transfer arms 34a and 34b: 2a (sec)

time to contract the transfer arms 34a and 34b: 2a (sec)

time to rotate the transfer arms 34a and 34b: 3a (sec)

“state in which the wafer W is not held by the pick 35”

time to extend the transfer arms 34a and 34b: a(sec)

time to contract the transfer arms 34a and 34b: a (sec)

time to rotate the transfer arms 34a and 34b: 2a (sec)

Next, as shown in FIG. 3C and 4, the transfer device 33 is rotated such that the pick 35a is positioned in front of the gate valve G6 to communicate with the load-lock chamber 41b and the pick 35b is positioned in front of the gate valve G2 to communicate with the load-lock chamber 41a. In this example, the transfer device 33 is rotated by about 120° in a counterclockwise direction. Then, the processed wafers Wa and WB are simultaneously unloaded into the load-lock chambers 41a and 41b from the transfer chamber 31 by using the transfer device 33, respectively. As illustrated, the processed wafers Wa and Wb are placed above or below unprocessed wafers W1 and W2 in the load-lock chambers 41a and 41b, respectively. The time needed to reach this state from the state shown in FIG. 3A is about 10a sec.

Thereafter, as shown in FIGS. 3D and 4, the unprocessed wafers W1 and W2 are simultaneously loaded into the transfer chamber 31 from the load-lock chambers 41a and 41b by using the transfer device 33, respectively. In this example, the unprocessed wafer W2 is held by the pick 35a, and the unprocessed wafer W1 is held by the pick 35b. The time needed to reach this state from the state shown in FIG. 3A is about 16a sec.

Next, as shown in FIGS. 3E and 4, the transfer device 33 is rotated such that the pick 35a is positioned in front of the gate valve G1 to communicate with the processing chamber 32a and the pick 35b is positioned in front of the gate valve G2 to communicate with the processing chamber 32b. In this example, the transfer device 33 is rotated by about 120° in a clockwise direction. Then, the unprocessed wafers W1 and W2 are simultaneously loaded into the processing chambers 32a and 32b from the transfer chamber 31 by using the transfer device 33, respectively. The time needed to reach this state from the state shown in FIG. 3A is about 22a sec.

Thereafter, as shown in FIGS. 3F and 4, the processed wafers Wa and Wb are unloaded from the load-lock chambers 41a and 41b, respectively. Next, the unprocessed wafers WA and WB are loaded into the load-lock chambers 41a and 41b, respectively. At this time, the transfer device 33 is rotated such that the pick 35a is positioned in front of the gate valve G3 to communicate with the processing chamber 32c and the pick 35b is positioned in front of the gate valve G4 to communicate with the processing chamber 32d. In this example, the transfer device 33 is rotated by about 120° in the clockwise direction. In other words, the process shown in FIG. 3F is a step returning to the process shown in FIG. 3A. The time needed to reach this state from the state shown in FIG. 3A is about 25a sec.

Thereafter, although it is not illustrated, the processed wafers Wx and Wy are simultaneously unloaded into the transfer chamber 31 from the processing chambers 32c and 32d and then unloaded into the load-lock chambers 41a and 41b from the transfer chamber 31, respectively, in the same sequence shown in FIGS. 3A to 3F. Next, the processed wafers Wx and Wy are unloaded from the load-lock chambers 41a and 41b, respectively. Further, the unprocessed wafers WA and WB are simultaneously loaded into the transfer chamber 31 from the load-lock chambers 41a and 41b and then loaded into the processing chambers 32c and 32d from the transfer chamber 31, respectively, in the same sequence shown in FIGS. 3D and 3E.

By repeating the processes shown in FIGS. 3A to 3F, a plurality of processed wafers are exchanged with a plurality of unprocessed wafers.

In accordance with the first embodiment, a plurality of processed wafers and a plurality of unprocessed wafers are simultaneously loaded and unloaded. In this example, two processed wafers and two unprocessed wafers are simultaneously loaded and unloaded, so that the loading and unloading operation of wafers can be performed in a shorter period of time compared to a transfer method for loading and unloading a single processed wafer and a single unprocessed wafer simultaneously. In this example, two processed wafers are exchanged with two unprocessed wafers for about 25a sec. The number of wafers that can be exchanged per one hour is roughly calculated as follows.

3600 sec÷25a sec×2=288/a

In accordance with the first example of the target object transfer method of the first embodiment, 288/a wafers can be exchanged for one hour.

The effect of time reduction will be described in comparison with that of a reference example.

### REFERENCE EXAMPLE

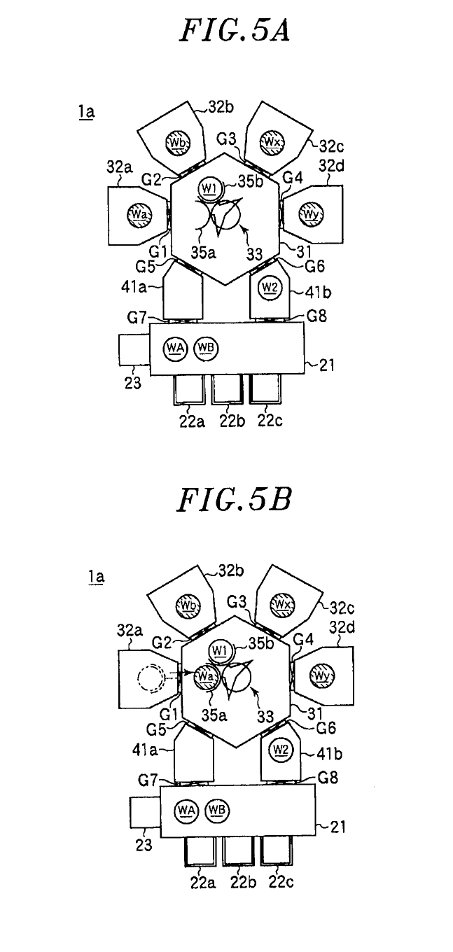

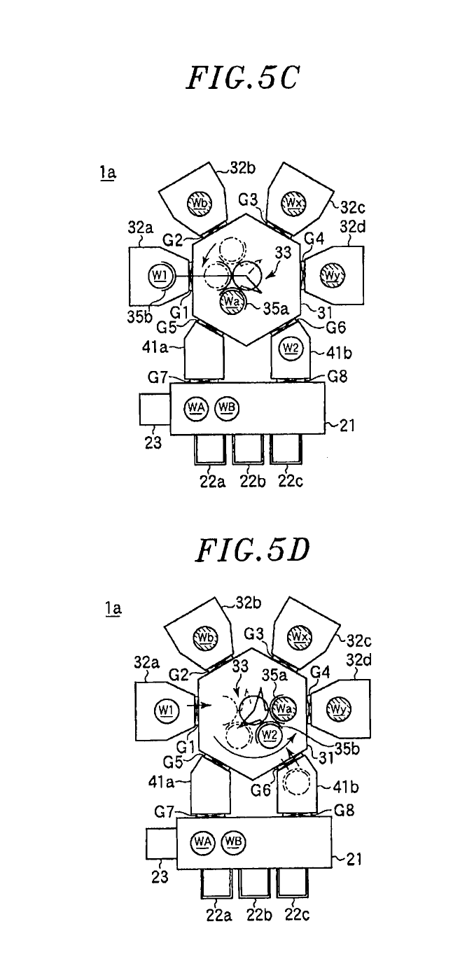

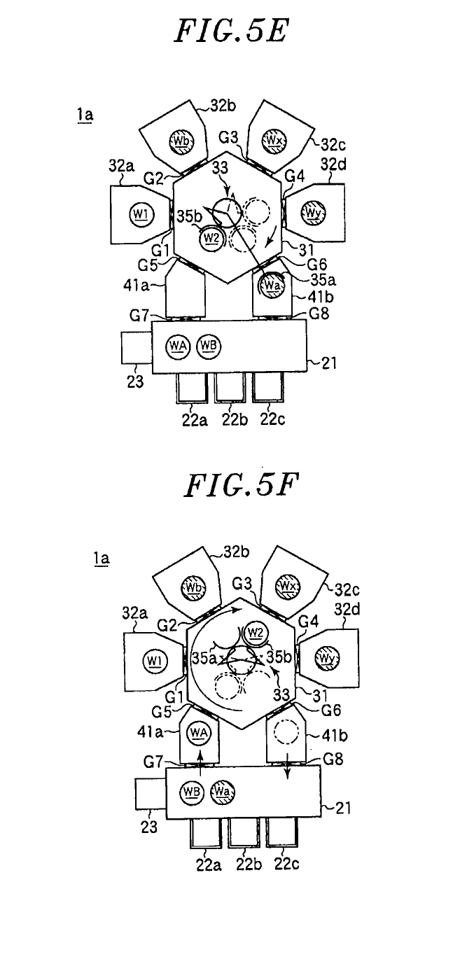

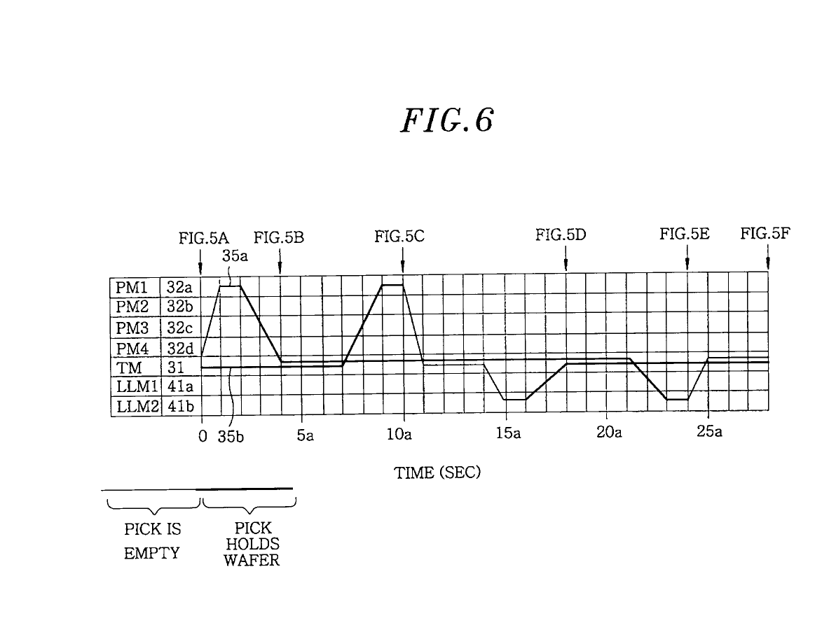

FIGS. 5A to 5F are top views showing the target object transfer method of the reference example. FIG. 6 is a timing diagram of the reference example.

As shown in FIGS. 5A and 6, an unprocessed wafer W1 is held by the pick 35b, and an unprocessed wafer W2 is loaded into the load-lock chamber 41b. The pick 35a of the transfer device 33 is positioned in front of the gate valve G1 to communicate the processing chamber 32a, and the pick 35b is positioned in front of the gate valve G2 to communicate with the processing chamber 32b.

Then, as shown in FIGS. 5B and 6, the processed wafer Wa is unloaded into the transfer chamber 31 from the processing chamber 32a by using the transfer device 33. The time needed to reach this state from the state shown in FIG. 5A is about 4a sec.

Next, as shown in FIGS. 5C and 6, the transfer device 33 is rotated by about 60° in the counterclockwise direction such that the pick 35a is positioned in front of the gate valve G5 to communicate with the load-lock chamber 41a and the pick 35b is positioned in front of the gate valve G1 to communicate with the processing chamber 32a. Then, the unprocessed wafer W1 is loaded into the processing chamber 32a from the transfer chamber 31 by using the transfer device 33. The time needed to reach this state from the state shown in FIG. 5A is about 10a sec.

Then, as shown in FIGS. 5D and 6, the transfer device is rotated by about 120° in the counterclockwise direction such that the pick 35a is positioned in front of the gate valve G4 to communicate with the processing chamber 32d and the pick 35b is positioned in front of the gate valve G6 to communicate with the load-lock chamber 41b. Thereafter, the unprocessed wafer W2 is loaded into the transfer chamber 31 from the load-lock chamber 41b. The time needed to reach this state from the state shown in FIG. 5A is about 18a sec.

Next, as shown in FIGS. 5E and 6, the transfer device 33 is rotated by about 60° in the clockwise direction such that the pick 35a is positioned in front of the gate valve G6 to communicate with the load-lock chamber 41b and the pick 35b is positioned in front of the gate valve G5 to communicate with the load-lock chamber 41a. Then, the processed wafer Wa is unloaded into the load-lock chamber 41b from the transfer chamber 31 by using the transfer device 33. The time needed to reach this state from the state shown in FIG. 5A is about 24a sec.

Next, as shown in FIGS. 5F and 6, the processed wafer Wa is unloaded from the load-lock chamber 41b and, then, the unprocessed wafer WA is loaded into the load-lock chamber 41a. At this time, the transfer device 33 is rotated such that the pick 35a is positioned in front of the gate valve G2 to communicate with the processing chamber 32b and the pick 35b is positioned in front of the gate valve G3 to communicate with the processing chamber 32c. The time needed to reach this state from the state shown in FIG. 5A is about 28a sec.

In the reference example, a single processed wafer and a single unprocessed wafer are simultaneously loaded and unloaded, and a single processed wafer is exchanged with a single unprocessed wafer for about 28a sec. The number of wafers that can be exchanged per one hour is roughly calculated as follows.

3600 sec 28a sec×1=128/a

In accordance with the first example of the target object transfer method of the first embodiment, 160/a wafers (=288/a−128/a) can be additionally exchanged per one hour compared to the reference example.

Accordingly, in accordance with the first embodiment in which the number of wafers that can be exchanged per unit time can be increased, it is possible to prevent a rate control factor for the time required for overall processing of a processing target object in the multi chamber type apparatus from being changed from the process rate control to the transfer rate control. Thus, even if the processing time is substantially reduced, the increase in the productivity is not limited.

### First Embodiment

### SECOND EXAMPLE

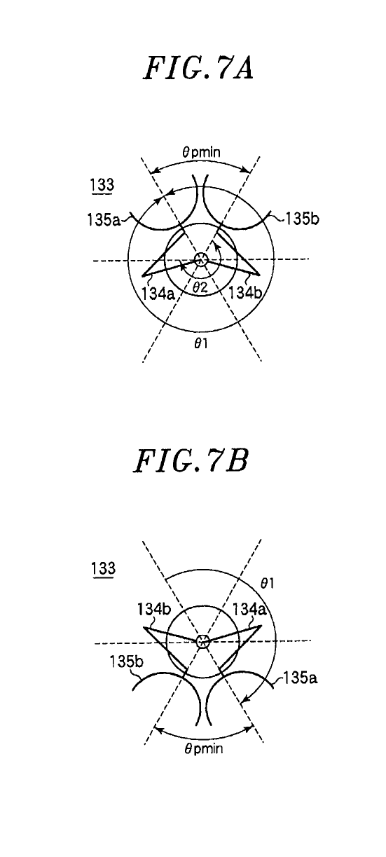

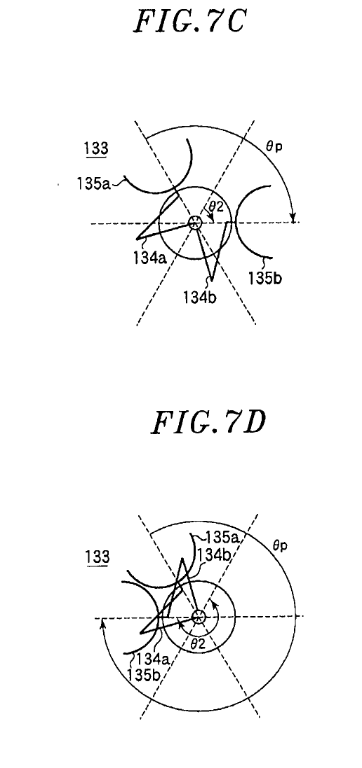

FIGS. 7A to 7D are top views schematically showing an example of a transfer device used in a second example of the target object transfer method in accordance with the first embodiment of the present invention.

As in the case of the transfer device 33 of FIG. 1, the transfer device 133 used in the second example has a plurality of extensible/contractible transfer arms 134 as shown in FIG. 7A. In this example, the transfer device 133 has two transfer arms 134a and 134b, and picks 135a and 135b are attached to leading ends of the transfer arms 134a and 134b, respectively. The transfer device 133 has, as rotation axes, a θ1 axis and a θ2 axis.

The θ1 axis rotates both of the transfer arms 134a and 134b. The θ1 axis can rotate endlessly. For example, the θ1 axis can rotate by about 180° from the state shown in FIG. 7A to the state shown in FIG. 7B in a clockwise direction or a counterclockwise direction and then rotate by about 180° from the state shown in FIG. 7B to the state shown in FIG. 7A in a clockwise direction or a counterclockwise direction.

The θ2 axis rotates the transfer arm 134b. For example, the θ2 axis can rotate by about 240° to 270° at maximum. In this example, the maximum rotation angle is set to about 240°. This is because the transfer chamber 31 has a hexagonal shape viewed from above and a minimum angle θpmin between the picks 135a and 135b is set to about 60° (360°−60°−60°=240°. For example, if the transfer chamber 31 has an octagonal shape viewed from above, the minimum angle θpmin between the picks 135a and 135b is set to about 45°. In this case, the maximum rotation angle of the θ2 axis is set to, e.g., about 270° (360°−45°−45°=270°. FIG. 7C shows the case in which the transfer arm 134b is rotated by about 60° in a clockwise direction by using the θ2 axis and the angle θp between the picks is increased to about 120° in the clockwise direction. FIG. 7D shows the case in which the transfer arm 134b is rotated by about 240° in the clockwise direction by using the θ2 axis and the angle θp between the picks is increased to about 300° in the clockwise direction.

The second example of the target object transfer method is performed by using the transfer device 133 capable of rotating only the transfer arm 134b. If the θ2 axis is not used in the transfer device 133, the first example of the target object transfer method can be carried out.

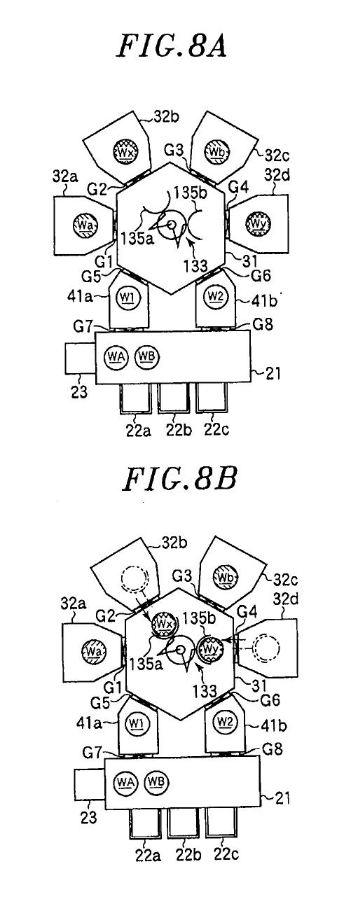

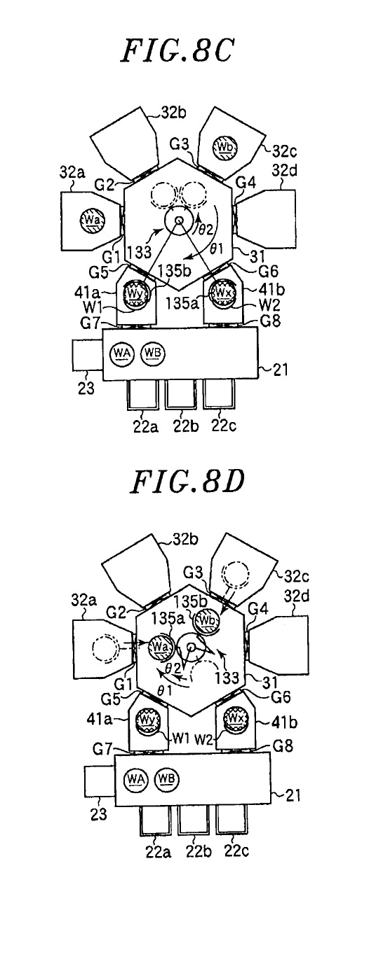

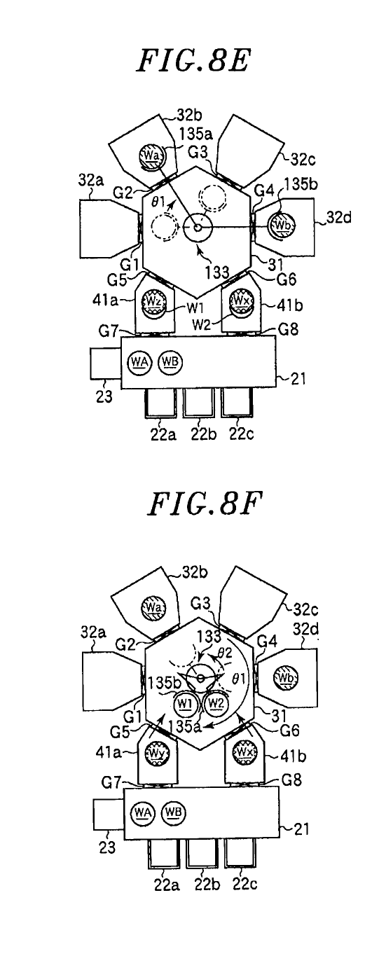

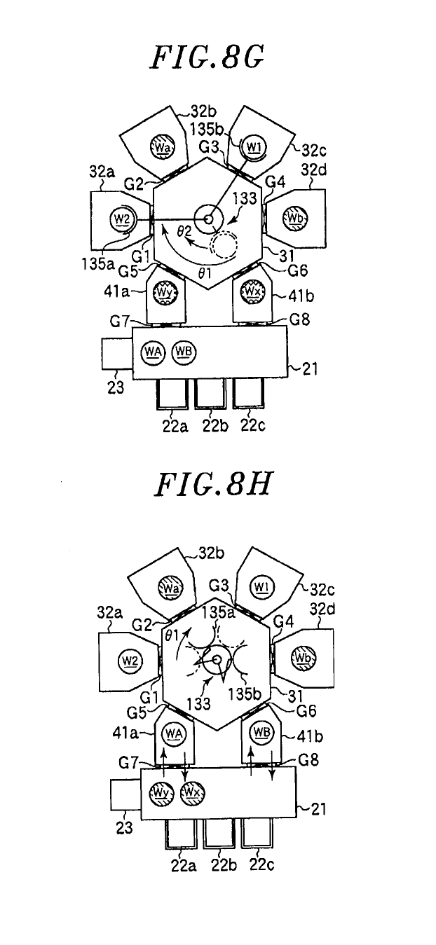

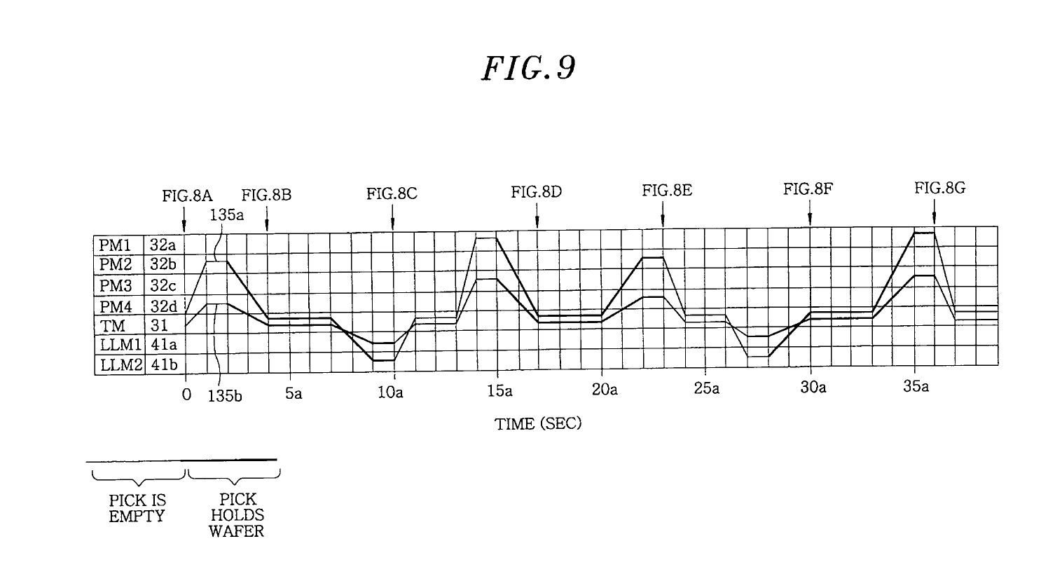

FIGS. 8A to 8H are top views showing the second example of the target object transfer method in accordance with the first embodiment of the present invention. FIG. 9 is a timing diagram of the second example. In the second example, after the processing in the processing chambers 32a and 32c is completed, another processing is performed in the processing chambers 32b and 32d.

First, as shown in FIGS. 8A and 9, unprocessed wafers W1 and W2 are loaded into the load-lock chambers 41a and 41b, respectively. At this time, the transfer device 133 is rotated such the pick 135a is positioned in front of the gate valve G2 to communicate with the processing chamber 32b and the pick 135b is positioned in front of the gate valve G4 to communicate with the processing chamber 32d. Further, the angle between the picks is increased to about 120°.

In the processing chambers 32a and 32c, the processing of the wafers Wa and Wb is completed. In the processing chambers 32b and 32d, the processing of the wafers Wx and Wy is completed.

Then, as shown in FIGS. 8B and 9, the processed wafers Wx and Wy are simultaneously unloaded into the transfer chamber 31 from the processing chambers 32b and 32d by using the transfer device 133, respectively. In this example, the processed wafers Wx and Wy are held by the picks 135a and 135b, respectively. The time needed to reach this state from the state shown in FIG. 8A is about 4a sec.

Next, as shown in FIGS. 8C and 9, the angle between the picks is reduced to about 60° by using the θ2 axis, and the transfer device 133 is rotated by using the θ1 axis such that the pick 135a is positioned in front of the gate valve G6 to communicate with the load-lock chamber 41b and the pick 135b is positioned in front of the gate valve G5 to communicate with the load-lock chamber 41a. In this example, the transfer device 133 is rotated by about 180° in the clockwise direction. Then, the processed wafers Wy and Wx are simultaneously unloaded into the load-lock chambers 41a and 41b from the transfer chamber 31 by using the transfer device 133, respectively. As illustrated, the processed wafers Wy and Wx are positioned above or below the unprocessed wafers W1 and W2 in the load-lock chambers 41a and 41b, respectively. The time needed to reach this state from the state shown in FIG. 8A is about 10a sec.

Then, as shown in FIGS. 8D and 9, the angle between the picks is increased to about 120° by using the θ2 axis, and the transfer device 133 is rotated by using the θ1 axis such that the pick 135a is positioned in front of the gate valve G1 to communicate with the processing chamber 32a and the pick 135b is positioned in front of the gate valve G3 to communicate with the processing chamber 32c. In this example, the transfer device 133 is rotated by about 150° in the clockwise direction. Then, the processed wafers Wa and Wb are simultaneously unloaded from the processing chambers 32a and 32c and loaded into the processing chamber 31 by using the transfer device 133, respectively. In this example, the processed wafers Wa and Wb are held by the picks 135a and 135b, respectively. The time needed to reach this state from the state shown in FIG. 8A is about 17a sec.

Thereafter, as shown in FIGS. 8E and 9, the transfer device 133 is rotated by using the θ1 axis such that the pick 135a is positioned in front of the gate valve G2 to communicate with the processing chamber 32b and the pick 135b is positioned in front of the gate valve G4 to communicate with the processing chamber 32d. In this example, the transfer device 133 is rotated by about 120° in the clockwise direction. Then, the processed wafers Wa and Wb are simultaneously loaded into the processing chambers 32b and 32d from the transfer chamber 31 by using the transfer device 133, respectively. The time needed to reach this state from the state shown in FIG. 8A is about 23a sec.

Then, as shown in FIGS. 8F and 9, the angel between the picks is reduced to about 60° by using the 62 axis, and the transfer device 133 is rotated by using the θ1 axis such that the pick 135a is positioned in front of the gate valve G6 to communicate with the load-lock chamber 41b and the pick 135b is positioned in front of the gate valve G5 to communicate with the load-lock chamber 41a. In this example, the transfer device 133 is rotated by about 180° in the clockwise direction. Then, the processed wafers W1 and W2 are simultaneously loaded into the transfer chamber 31 from the load-lock chambers 41a and 41b by using the transfer device 133, respectively. The unprocessed wafers W1 and W2 are held by the picks 135b and 135a, respectively. The time needed to reach this state from the state shown in FIG. 8A is about 30a sec.

Next, as shown in FIGS. 8G and 9, the angle between the picks is increased to about 120° by using the θ2 axis, and the transfer device 133 is rotated by using the θ1 axis such that the pick 135a is positioned in front of the gate valve G1 to communicate with the processing chamber 32a and the pick 135b is positioned in front of the gate valve G3 to communicate with the processing chamber 32c. In this example, the transfer device 133 is rotated by about 150° in the clockwise direction. Then, the unprocessed wafers W1 and W2 are simultaneously loaded from the transfer chamber 31 and loaded into the processing chambers 32a and 32c by using the transfer device 133, respectively. The time needed to reach this state from the state shown in FIG. 8A is about 36a sec.

Then, as shown in FIGS. 8H and 9, the processed wafers Wx and Wy are unloaded from the load-lock chambers 41a and 41b, respectively. Next, the unprocessed wafers WA and WB are loaded into the load-lock chambers 41a and 41b, respectively. At this time, the transfer device 133 is rotated such that the pick 135a is positioned in front of the gate valve G2 to communicate with the processing chamber 32b and the pick 135b is positioned in front of the gate valve G4 to communicate with the processing chamber 32d. In this example, the transfer device 133 is rotated by about 60° in the clockwise direction. In other words, the process shown in FIG. 8H is a step returning to the process shown in FIG. 8A. The time needed to reach this state from the state shown in FIG. 8A is about 39a sec.

Thereafter, although it is not illustrated, the processed wafers Wa and Wb are simultaneously unloaded into the transfer chamber 31 from the processing chambers 32b and 32d and then unloaded into the load-lock chambers 41a and 41b from the transfer chamber 31, respectively, in the same sequence shown in FIGS. 8A to 8H.

Then, the processed wafers W1 and W2 are simultaneously unloaded into the transfer chamber 31 from the processing chambers 32a and 32c and then loaded into the processing chambers 32b and 32d from the transfer chamber 31, respectively.

Next, the unprocessed wafers WA and WB are simultaneously loaded into the transfer chamber 31 from the load-lock chambers 41a and 41b and then loaded into the processing chambers 32a and 32c from the transfer chamber 31, respectively.

By repeating the processes shown in FIGS. 8A to 8H, a plurality of processed wafers is transferred to a next processing, and a plurality of completely processed wafers is exchanged with a plurality of unprocessed wafers.

In the second example as well as in the first example of the target object transfer method, a plurality of, e.g., two in the second example, processed wafers and unprocessed wafers are simultaneously loaded and unloaded. Therefore, the loading and unloading operation of wafers can be performed in a shorter period of time. In this example, two processed wafers can be exchanged with two unprocessed wafers for about 39a sec, so that the number of wafers that can be exchanged per one hour is roughly calculated as follows.

3600 sec÷39a sec×2=about 184.6/a

In accordance with the transfer device 133 shown in FIGS. 7A to 7D, the transfer arms 134a and 134b can operate individually. Thus, when the exchange of wafers is required, the pick 135a or 135b holding the wafer W unloaded from the processing chambers 32a to 32d can be moved toward the load-lock chamber 41a or 41b accommodating therein a wafer to be exchanged.

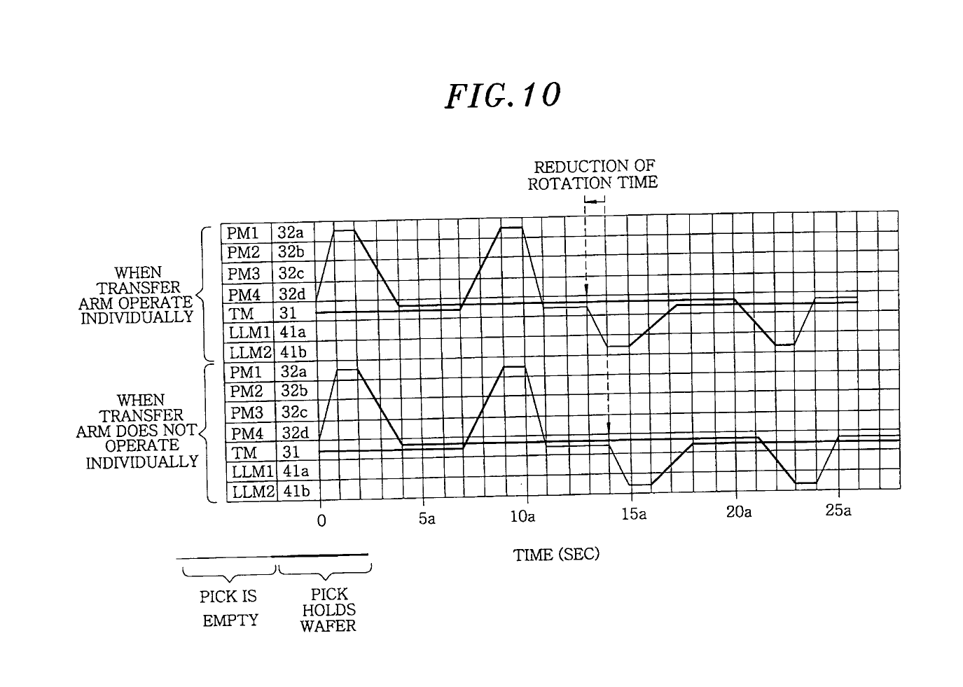

Accordingly, as shown in the timing diagram of FIG. 10, the rotation time of the transfer arm can be reduced compared to the transfer device 133 having the transfer arms 34a and 34b which do not operate individually.

### First Embodiment

### Third Example

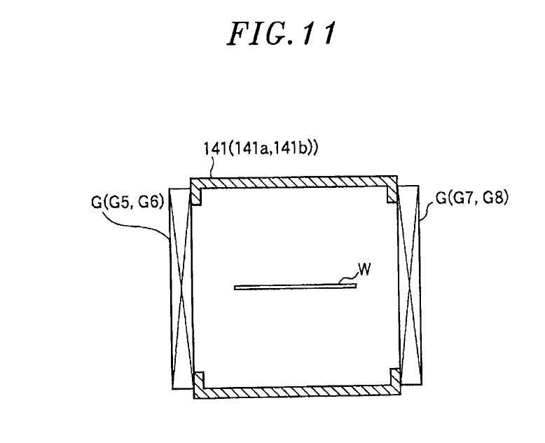

FIG. 11 is a cross sectional view showing an example of a load-lock chamber that can be used in a third example of the target object transfer method in accordance with the first embodiment of the present invention.

In the first and the second example, the load-lock chambers 41a and 41b capable of accommodating a plurality of wafer W are used. In the third example, even if the load-lock chamber 141 (141a or 141b) can accommodate only one wafer W as shown in FIG. 11, the transfer methods of the first and the second example can be carried out.

In the third example, the transfer device 133 of FIG. 7 which has the θ1 axis for rotating both of the transfer arms 134a and 134b and the θ2 axis for rotating the transfer arm 134b is used.

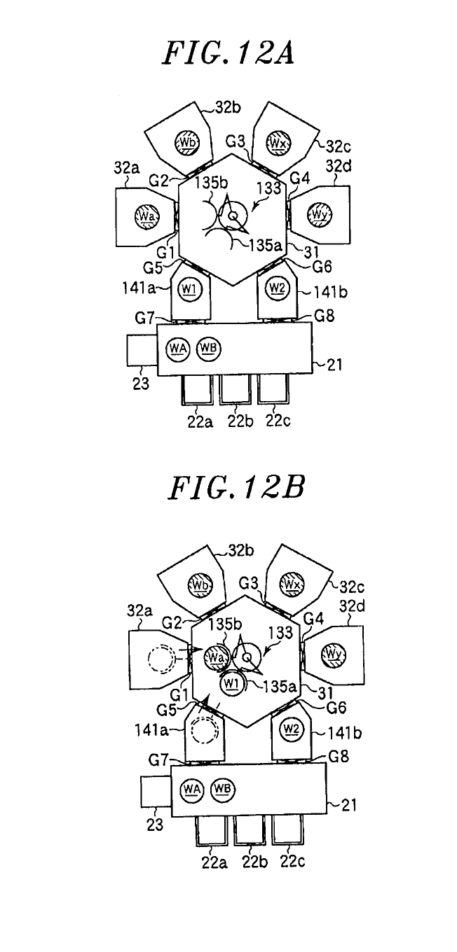

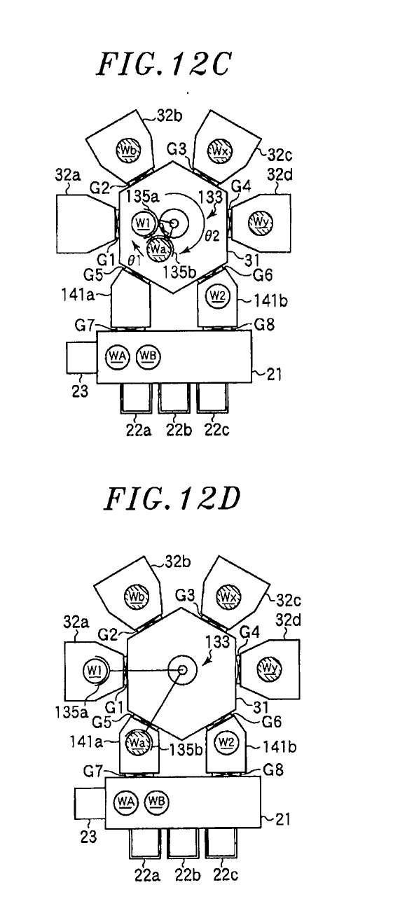

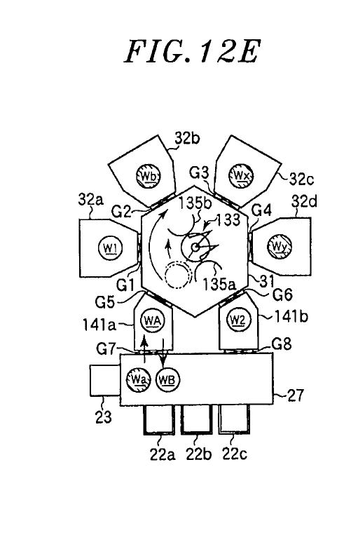

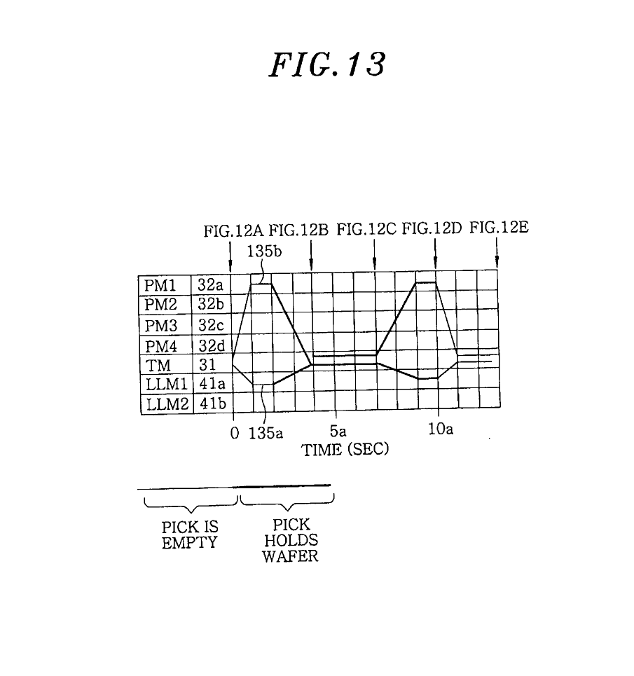

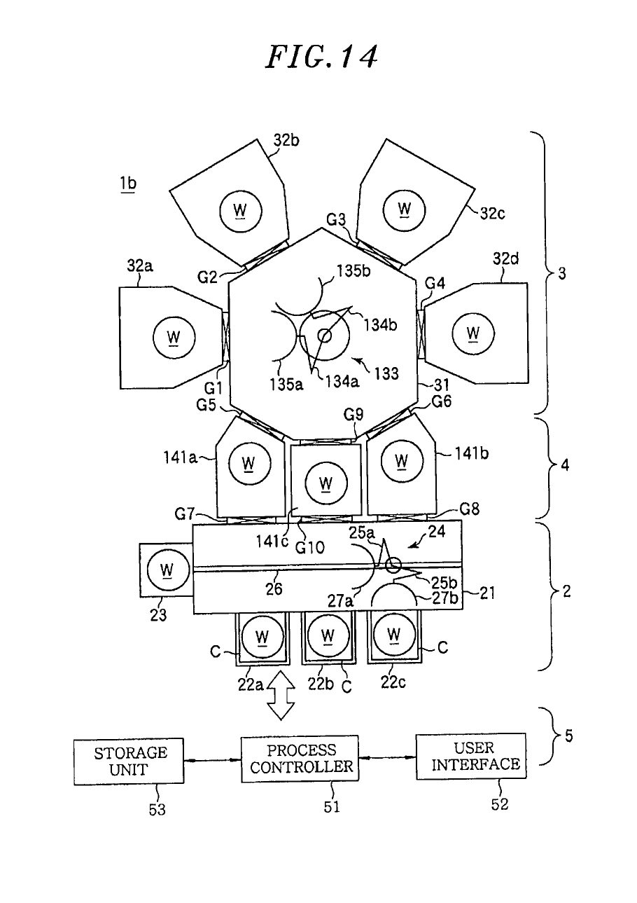

FIGS. 12A to 12E are top views showing the third example of the target object transfer method in accordance with the first embodiment of the present invention. FIG. 13 is a timing diagram of the third example.

First, as shown in FIGS. 12A and 13, unprocessed wafers W1 and W2 are loaded into the load-lock chambers 141a and 141b, respectively. At this time, the transfer device 133 is rotated such that the picks 135a is positioned in front of the gate valve G5 to communicate with the load-lock chamber 141a and the pick 135b is positioned in front of the gate valve G1 to communicate with the processing chamber 32a.

In the processing chamber 32a, the processing of the wafer Wa is completed.

Then, as shown in FIGS. 12B and 13, the unprocessed wafers W1 and the processed wafer Wa are simultaneously loaded from the load-lock chamber 141a and unloaded from the processing chamber 32a into the transfer chamber 31 by using the transfer device 133, respectively. In this example, the unprocessed wafers W1 and the processed wafer Wa are held by the picks 135a and 135b, respectively. The time needed to reach this state from the state shown in FIG. 12A is about 4a sec.

Next, as shown in FIGS. 12C and 13, the angle between the picks is increased to about 240° by using the θ2 axis, and the transfer device 133 is rotated by using the θ1 axis such that the pick 135a is positioned in front of the gate valve G1 to communicate with the processing chamber 32a and the pick 135b is positioned in front of the gate valve G5 to communicate with the load-lock chamber 141a. In this example, the transfer device 133 is rotated by about 60° in the clockwise direction. The time needed to reach this state from the state shown in FIG. 12A is about 7a sec.

Then, as shown in FIGS. 12D and 13, the processed wafer Wa and the unprocessed wafer W1 are simultaneously unloaded into the load-lock chamber 141a and loaded into the processing chamber 32a from the transfer chamber 31 by using the transfer device 133, respectively. The time needed to reach this state from the state shown in FIG. 12A is about 10a sec.

Then, as shown in FIGS. 12E and 13, the processed wafer Wa is unloaded from the load-lock chamber 141a. Next, the unprocessed wafer WA is loaded into the load-lock chamber 141a. Further, the angle between the picks is reduced to about 180° by using the θ2 axis, and the transfer device 133 is rotated by using the 61 such that the pick 135a is positioned in front of the gate valve G6 to communicate with the load-lock chamber 141b and the pick 135b is positioned in front of the gate valve G2 to communicate with the processing chamber 32b. In this example, the transfer device 133 is rotated by about 120° in the clockwise direction. The process shown in FIG. 12E is a step returning to the process shown in FIG. 12A. The time needed to reach this state from the state shown in FIG. 12A is about 13a sec.

Thereafter, although it is not illustrated, the processed wafer Wb and the unprocessed wafer W2 are simultaneously unloaded into the transfer chamber 31 from the processing chamber 32b and loaded into the load-lock chamber 141b and then unloaded into the load-lock chamber 141b and loaded the processing chamber 32b from the transfer chamber 31, respectively, in the same sequence shown in FIGS. 12A to 12E. Next, the processed wafer Wb is unloaded from the load-lock chamber 141b, and the unprocessed wafer WB is loaded into the load-lock chamber 141b.

By repeating the processes shown in FIGS. 12A to 12E, processed wafers and unprocessed wafers are exchanged with unprocessed wafers and processed wafers.

In accordance with the third example, the processed wafers and the unprocessed wafers are simultaneously loaded and unloaded, so that the loading and unloading operation of wafers can be completed in a shorter period of time compared to when the processed wafers and the unprocessed wafers are separately loaded and unloaded. In this example, since the processed wafers and the unprocessed wafers are simultaneously loaded and unloaded, the processed wafers can be exchanged with the unprocessed wafers for about 13a sec. In this example, the number of wafers that can be exchanged per one hour is roughly calculated as follows.

3600 sec÷13a sec×1=about 277/a

In the first and the second example, a plurality of unprocessed wafers and a plurality of processed wafers are simultaneously loaded and unloaded. Therefore, the number of wafers W that can be held by the transfer device 33 or 133 is preferably equal to the number of the load-lock chambers 41. For example, when two wafers W can be held by the transfer device 33 or 133, the transfer device 33 or 133 operates to hold two unprocessed wafers W simultaneously. Hence, two load lock chambers are required as in the case of providing the load-lock chambers 41a and 41b shown in FIG. 1.

In the third example, the processed wafer and the unprocessed wafer are simultaneously transferred. Accordingly, the transfer device 133 operates to hold at least one unprocessed wafer W, and at least one load-lock chamber is required. Since, however, the time is required to decrease the pressure from the atmospheric pressure or increase the pressure to the atmospheric pressure, two load-lock chambers 41 may be provided as in the third example.

Furthermore, a third load-lock chamber 141c may be provided as shown in FIG. 14. As shown in FIG. 14, the semiconductor manufacturing device 1b includes a third load-lock chamber 141c communicating with the transfer chamber 31 via a gate valve G9 and communicating with the loader unit 21 via a gate valve G10.

In the third example, the number of load-lock chambers may be set to be greater than the number of wafers W that can be held by the transfer device 133.

### Second Embodiment

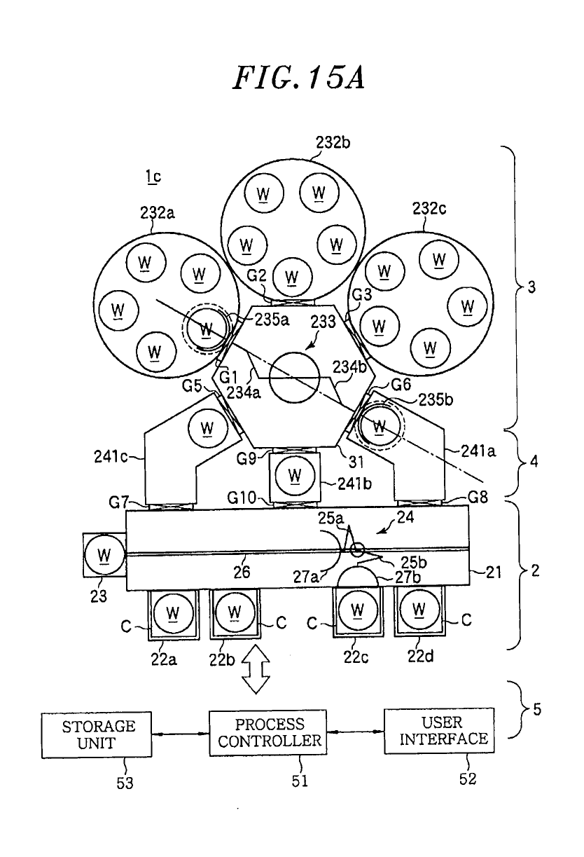

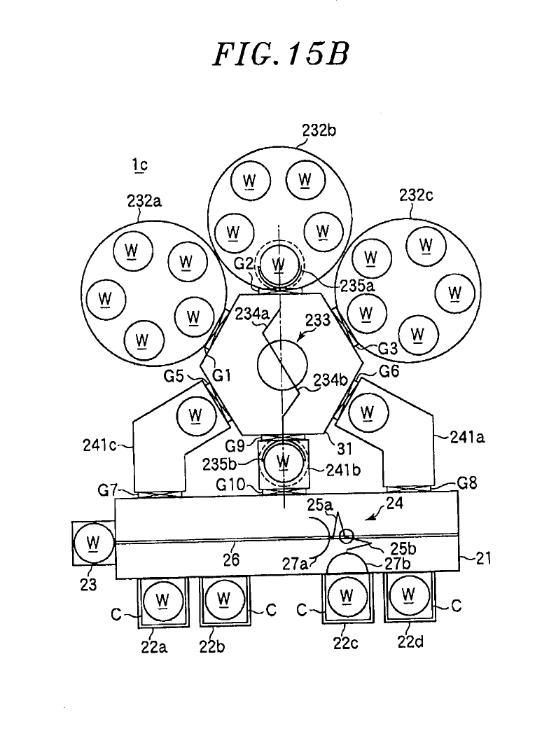

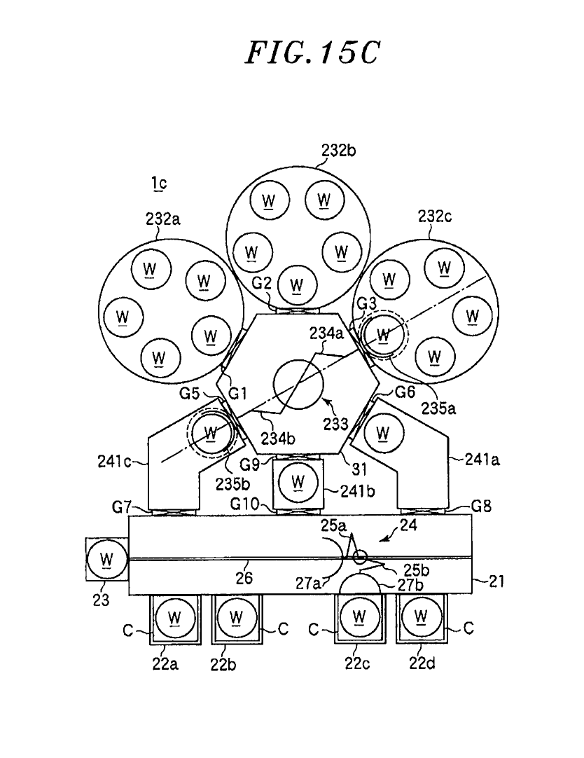

FIGS. 15A to 15C are top views schematically showing an example of a target object processing apparatus capable of performing a target object transfer method in accordance with a second embodiment of the present invention. In this example as well, a multi chamber (cluster tool) type semiconductor manufacturing apparatus using a semiconductor wafer as a target object is employed as an example of the target object processing apparatus.

As shown in FIGS. 15A to 15C, the semiconductor manufacturing device 1c is different from the semiconductor manufacturing device 1a of FIG. 1 in that the load-lock chambers 241a to 241c are arranged linearly so as to correspond to the processing chambers 232a to 232c, respectively, and also in that the transfer device 233 provided in the transfer chamber 31 is configured to simultaneously load and unload the wafers W between the transfer chamber 31 and one of the processing chambers 232a to 232c and one of the load-lock chambers 241a to 241c which is arranged linearly with respect to the corresponding processing chamber.

FIG. 15A shows a state in which the transfer device 233 simultaneously loads and unloads wafers W between the processing chamber 232a and the load-lock chamber 241a arranged linearly with respect to the processing chamber 232a via the transfer chamber 31. To be specific, the transfer arm 234a of the transfer device 233 is extended toward the processing chamber 232a so that the pick 235a attached to the leading end of the transfer arm 234a holds the wafer W accommodated in the processing chamber 232a, and the transfer arm 234b is extended toward the load-lock chamber 241a so that the pick 235b attached to the leading end of the transfer arm 234b holds the wafer W accommodated in the load-lock chamber 241a. When the transfer arms 234a and 234b are extended, the picks 235a and 235b are pushed away in the opposite direction. When the transfer arms 234a and 234b are contracted, the picks 235a and 235b are pulled in the same direction.

FIG. 15B shows a state in which the transfer device 233 simultaneously loads and unloads the wafers W between the processing chamber 232b and the load-lock chamber 241b arranged linearly with respect to the processing chamber 232b via the transfer chamber 31. FIG. 15C shows a state in which the transfer device 233 simultaneously loads and unloads the wafers W between the processing chamber 232c and the load-lock chamber 241c arranged linearly with respect to the processing chamber 232c via the transfer chamber 31.

In this example, each of the processing chambers 232a to 232c is configured to process a plurality of wafers W at a time. In this example, five wafers can be processed at a time.

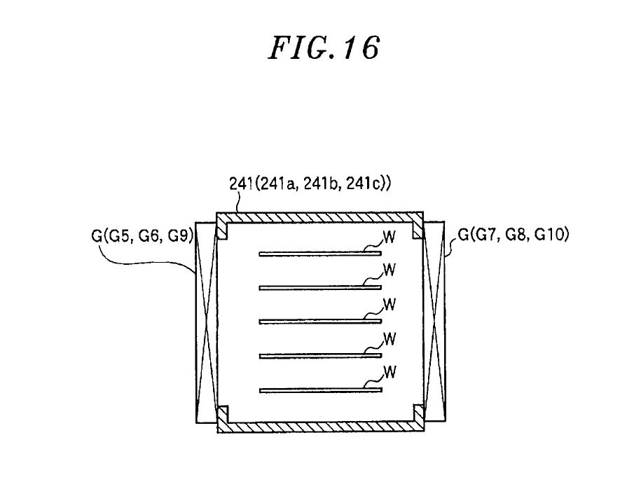

Further, in this example, each of the load-lock chambers 241a to 241c is configured to accommodate a plurality of wafers W as shown in FIG. 16. In this example, the number of wafers W that can be accommodated is equal to the number of wafers W that can be simultaneously processed in each of the processing chambers 232a to 232c. To be specific, five wafers W can be accommodated in each of the load-lock chambers 241a to 241c.

Hereinafter, an example of the target object transfer method in accordance with a second embodiment of the present invention will be described.

### Second Embodiment

### FIRST EXAMPLE

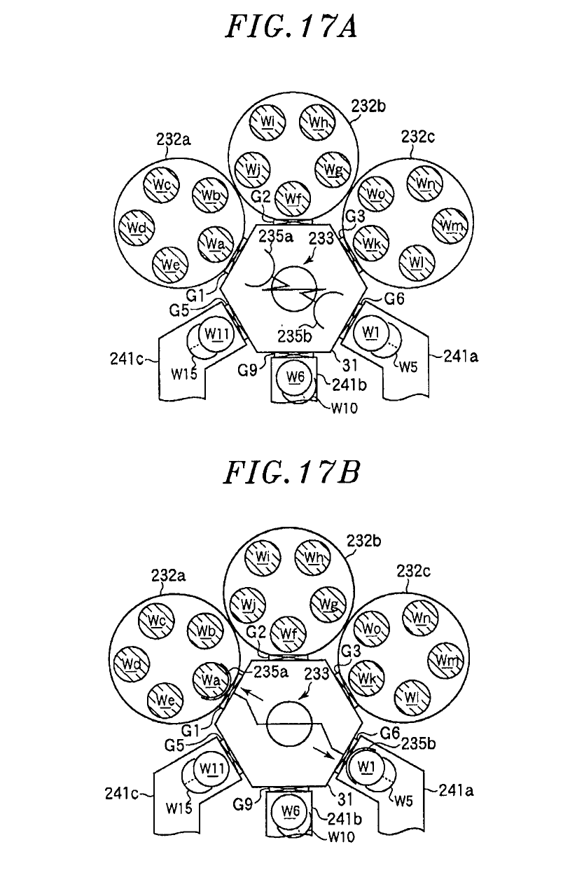

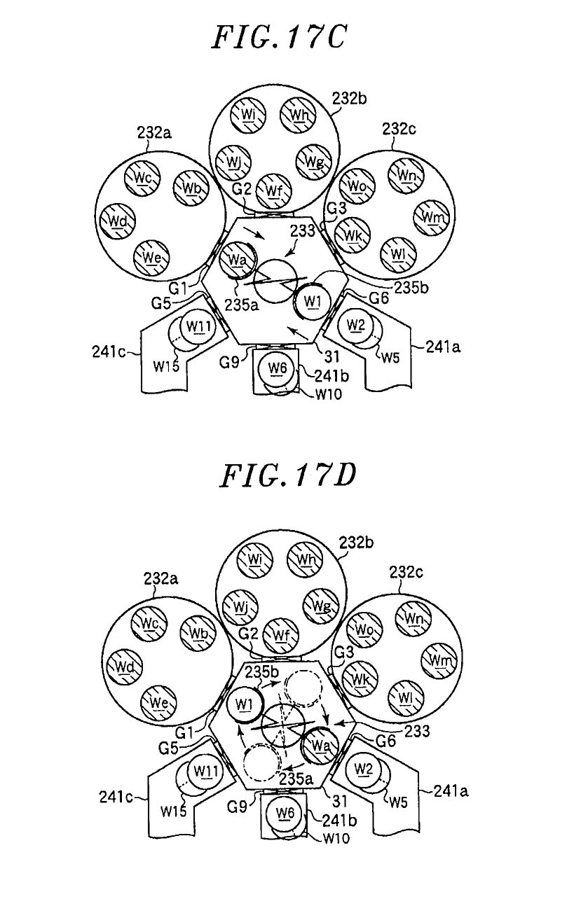

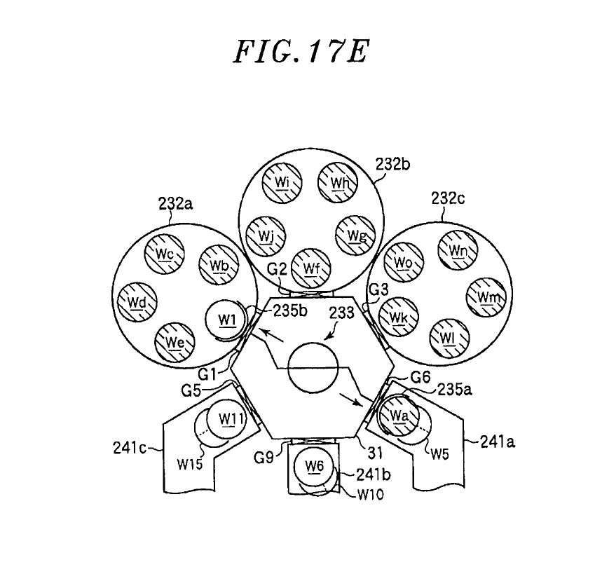

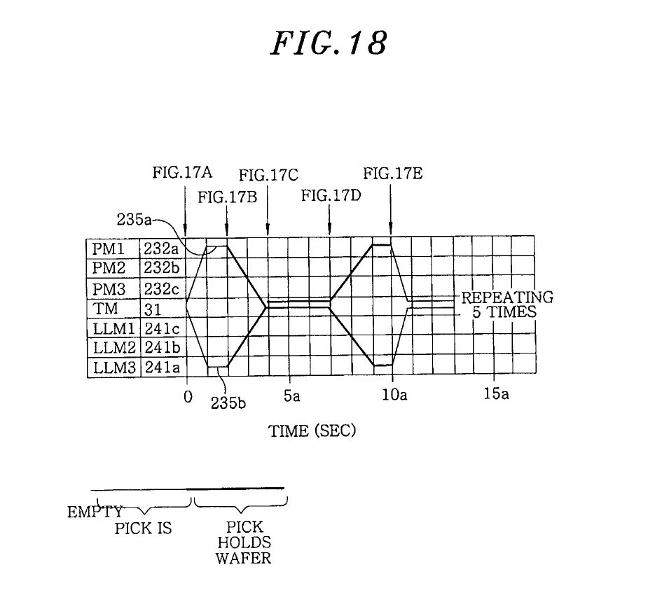

FIGS. 17A to 17E are top views showing a first example of the target object transfer method in accordance with the second embodiment of the present invention. FIG. 18 is a timing diagram of the first example.

First, as shown in FIGS. 17A and 18, unprocessed wafers W1 to W5, W6 to W10, and W11 to W15 are loaded into the load-lock chambers 241a to 241c, respectively. At this time, the transfer device 233 is rotated such that the pick 235a is positioned in front of the gate valve G1 to communicate with the processing chamber 232a and the picks 235b is positioned in front of the gate valve G6 to communicate with the load-lock chamber 241a. In the processing chamber 232a, the processing of the wafers Wa to Wb is completed.

Then, as shown in FIGS. 17B and 18, the picks 235a is extended toward the processing chamber 232a, and the pick 235b is extended toward the load-lock chamber 241a. The processed wafer Wa is held by the pick 235a, and the unprocessed wafer W1 is held by the pick 235b. The time needed to reach this state from the state shown in FIG. 17A is about 2a sec.

Next, as shown in FIGS. 17C and 18, the picks 235a and 235b are retracted toward the transfer chamber 31, and the unprocessed wafer W1 is loaded into the transfer chamber 31 from the load-lock chamber 241a and the processed wafer Wa is unloaded into the transfer chamber 31 from the processing chamber 232a, simultaneously. The time needed to reach this state from the state shown in FIG. 17A is about 4a sec.

Thereafter, as shown in FIGS. 17D and 18, the transfer device 233 is rotated by about 180° such that the pick 235a is positioned in front of the gate valve G6 to communicate with the load-lock chamber 241a and the pick 235b is positioned in front of the gate valve G1 to communicate with the processing chamber 232a. The time needed to reach this state from the state shown in FIG. 17A is about 7a sec.

Next, as shown in FIGS. 17E and 18, the pick 235b is extended toward the processing chamber 232a, and the pick 235a is extended toward the load-lock chamber 241a. The unprocessed wafer W1 is loaded into the processing chamber 232a from the transfer chamber 31, and the processed wafer Wa is unloaded into the load-lock chamber 241a from the transfer chamber 31. The time needed to reach this state from the state shown in FIG. 17A is about 10a sec.

Thereafter, although it is not illustrated, the transfer arm 234a and 234b are extended such that the pick 235b is positioned in front of the gate valve G1 to communicate with the processing chamber 232a; and the pick 235a is positioned in front of the gate valve G6 to communicate with the load-lock chamber 241a. This process is a step returning to the process shown in FIG. 17A. The time needed to reach this state from the state shown in FIG. 17A is about 13a sec.

Then, the processed wafer Wb and the unprocessed wafer W2 are simultaneously unloaded into the transfer chamber 31 from the processing chamber 232a and the load-lock chamber 241a and then unloaded into the load-lock chamber 241a from the transfer chamber 31 and into the processing chamber 232a from the transfer chamber 31, respectively, in the same sequence shown in FIGS. 17A to 17E. Such operations are repeated five times until the processing of wafers W5 and We is completed.

By repeating the processes shown in FIGS. 17A to 17E, processed wafers and unprocessed wafers are exchanged with unprocessed wafers and processed wafers.

The same operations are performed between the processing chamber 232b and the load-lock chamber 241b and between the processing chamber 232c and the load-lock chamber 241c. In other words, the processes shown in FIGS. 17A to 17E are repeated as many as the number of the processing chambers 232a to 232c, i.e., three times in this example.

In this example, the processed wafers and the unprocessed wafers are simultaneously loaded and unloaded, so that the processed wafers can be exchanged with the unprocessed wafers for about 13a sec. In this example, the number of wafers that can be exchanged per one hour is roughly calculated as follows.

3600 sec÷13a sec×1=about 277/a

### Second Embodiment

### SECOND EXAMPLE

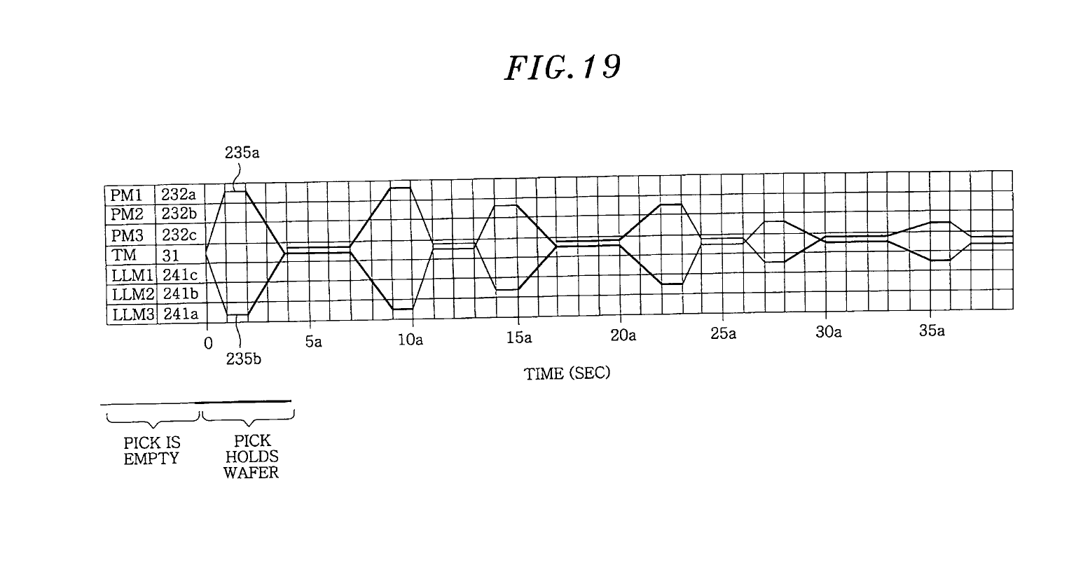

FIG. 19 is a timing diagram of a second example of the target object transfer method in accordance with the second embodiment of the present invention.

As shown in FIG. 19, the second example of the second embodiment is different from the first example of the second embodiment shown in FIGS. 17A to 17E in that the simultaneous loading and unloading of unprocessed wafers W and processed wafers W is sequentially performed between the processing chamber 232a and the load-lock chamber 241a, then between the processing chamber 232b and the load-lock chamber 241b, and then between the processing chamber 232c and the load-lock chamber 241c. Such processes are repeated as many as the number of wafers, i.e., five times in this example. The others are the same as those of the first example of the second embodiment.

In this example as well, processed wafers and unprocessed wafers are simultaneously loaded and unloaded. Further, three processed wafers in the processing chambers 232a to 232c can be exchanged with unprocessed wafers for about 39a sec. In this example, the number of wafers that can be exchanged per one hour is roughly calculated as follows.

3600 sec÷(39a sec÷3)=about 277/a

### Second Embodiment

### THIRD EXAMPLE

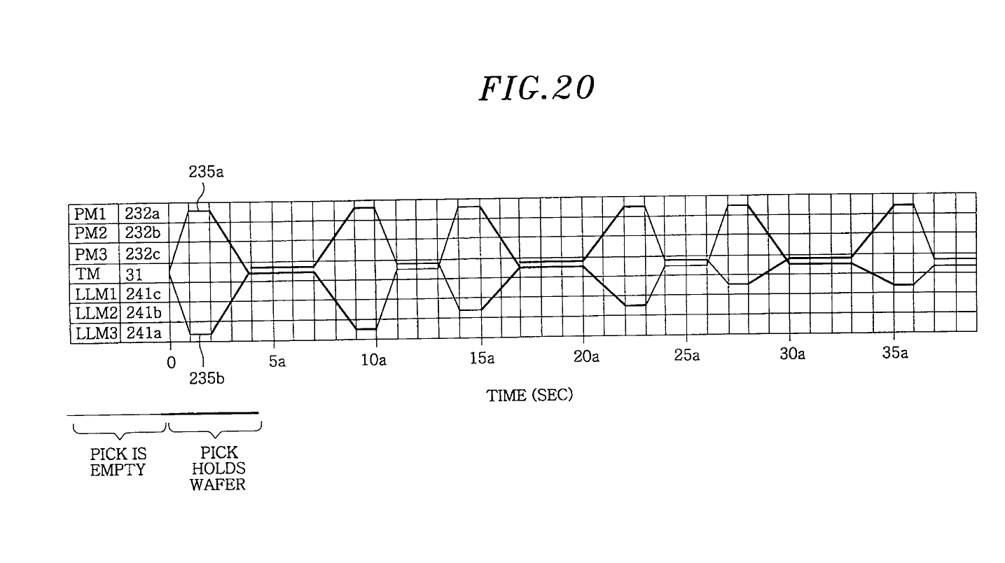

FIG. 20 is a timing diagram of a third example of the target object transfer method in accordance with the second embodiment of the present invention.

As shown in FIG. 20, the third example of the second embodiment is different from the second example of the second embodiment shown in FIG. 19 in that the simultaneously loading and unloading of unprocessed wafers W and processed wafers W is sequentially performed between the processing chamber 232a and the load-lock chamber 241a, then between the processing chamber 232a and the load-lock chamber 241b, and then between the processing chamber 232a and the load-lock chamber 241c. The others are the same as those of the second example of the second embodiment.

In this example as well, processed wafers and unprocessed wafers are simultaneously loaded and unloaded. Moreover, three processed wafers in the processing chambers 232a to 232c can be exchanged with unprocessed wafers for about 39a sec. In this example, the number of wafers that can be exchanged per one hour is roughly calculated as follows.

3600 sec÷(39a sec÷3)=about 277/a

In accordance with the target object transfer method of the second embodiment, processed wafers and unprocessed wafers are simultaneously loaded and unloaded, so that the loading and unloading operation of wafers can be performed in a shorter period of time compared to when processed wafers and unprocessed wafers are separately loaded and unloaded.

In the second embodiment, the load-lock chambers 241a to 241c are arranged linearly so as to correspond to the processing chambers 232a to 232c via the transfer chamber 31, respectively. Therefore, simply by rotating the transfer device 233 by about 180°, an unprocessed wafer and a processed wafer can be moved toward one of the processing chambers 232a to 232c and one of the load-lock chambers 241a to 241c, respectively. Accordingly, it is unnecessary to adjust the angle between the picks, and the loading and unloading operation of the wafers can be performed in a shorter period of time.

While the invention has been shown and described with respect to the embodiments, various changes and modifications may be made without departing from the scope of the invention.

For example, the number of the processing chambers 32 in the first embodiment is four and the number of processing chambers 232 in the second embodiment is three. However, the number of the processing chambers 32 or 232 is not limited to thereto.

Besides, the present invention can be variously modified without departing from the scope of the invention.

1. A target object transfer method for a target object processing apparatus, which includes a transfer chamber in which a transfer device for transferring target objects is provided, processing chambers disposed around the transfer chamber to process the target objects, and one or more load-lock chambers disposed around the transfer chamber to convert an environment around the target objects to an environment inside the transfer chamber, each load-lock chamber being configured to accommodate therein parts of the target objects, the method comprising:
(0) loading unprocessed first target objects into the load-lock chambers;
(1) simultaneously unloading processed second target objects into the transfer chamber from the processing chambers by using the transfer device;
(2) simultaneously unloading the processed second target objects into the load-lock chambers from the transfer chamber by using the transfer device;
(3) simultaneously loading the unprocessed first target objects into the transfer chamber from the load-lock chambers by using the transfer device;
(4) simultaneously loading the unprocessed first target objects into the processing chambers from the transfer chamber by using the transfer device;
(5) unloading the processed second target objects from the load-lock chambers.

2. A target object transfer method for a target object processing apparatus, which includes a transfer chamber in which a transfer device for transferring target objects is provided, processing chambers disposed around the transfer chamber to process the target objects, and load-lock chambers disposed around the transfer chamber to convert an environment around the target objects to an environment inside the transfer chamber, each load-lock chamber being configured to accommodate therein parts of the target objects, the method comprising:
(0) loading unprocessed first target objects into the load-lock chambers;
(1) simultaneously unloading processed second target objects into the transfer chamber from a part of the processing chambers by using the transfer device;
(2) simultaneously unloading the processed second target objects into the load-lock chambers from the transfer chamber by using the transfer device;
(3) simultaneously unloading processed third target objects into the transfer chamber from another part of the processing chambers other than the part of the processing chambers by using the transfer device;
(4) simultaneously loading the processed third target objects into the transfer chamber from said another part of the processing chambers by using the transfer device;
(5) simultaneously loading the unprocessed first target objects into the transfer chamber from the load-lock chambers by using the transfer device;
(6) simultaneously loading the unprocessed first target objects into the transfer chamber from the load-lock chambers by using the transfer device; and
(7) unloading the processed second target objects from the load-lock chambers.

3. The target object transfer method of claim 1, wherein the maximum number of target objects allowed to be simultaneously held by the transfer device is equal to the number of load-lock chambers.

4. A target object processing apparatus comprising:
a transfer chamber in which a transfer device for transferring target objects is provided;
processing chambers, disposed around the transfer chamber, for processing the target objects; and
load-lock chambers, disposed around the transfer chamber, for converting an environment around the target objects to an environment inside the transfer chamber, wherein each of the load-lock chambers is configured to accommodate parts of the target objects, and
wherein the transfer device is configured to simultaneously transfer the target objects between the processing chambers and the transfer chamber, between the transfer chamber and the load-lock chambers, and between a first part of the processing chambers and a second part of the processing chambers other than the first part of the processing chambers.

5. The target object processing apparatus of claim 4, wherein the maximum number of target objects allowed to be simultaneously held by the transfer device is equal to the number of load-lock chambers.

6. A target object transfer method for a target object processing apparatus, which includes a transfer chamber in which a transfer device for transferring target objects is provided, processing chambers disposed around the transfer chamber to process the target objects, and load-lock chambers disposed around the transfer chamber to convert an environment around the target objects to an environment inside the transfer chamber, the method comprising:
(0) loading unprocessed first target objects into the load-lock chambers;
(1) simultaneously transferring at least one of processed second target objects and at least one of the unprocessed first target objects into the transfer chamber from at least one of the processing chambers and at least one of the load-lock chambers by using the transfer device;
(2) simultaneously transferring said at least one of the processed second target objects and said at least one of the unprocessed first target objects from the transfer chamber into said at least one of the load-lock chambers and said at least one of the processing chambers by using the transfer device; and
(3) unloading said at least one of the processed second target objects from said at least one of the load-lock chambers.

7. The target object transfer method of claim 6, wherein the number of the load-lock chambers is greater than the maximum number of the target objects allowed to be simultaneously held by the transfer device.

8. A target object processing apparatus comprising:
a transfer chamber in which a transfer device for transferring target objects is provided;
processing chambers, disposed around the transfer chamber, for processing the target objects; and
load-lock chambers, disposed around the transfer chamber, for converting an environment around the target objects to an environment inside the transfer chamber,
wherein the transfer device is configured to simultaneously transferring the target objects between at least one of the processing chambers and at least one of the load-lock chambers.

9. The target object transfer method of claim 8, wherein the number of the load-lock chambers is greater than the maximum number of the target objects allowed to be simultaneously held by the transfer device.

10. A target object transfer method for a target object processing apparatus, which includes a transfer chamber in which a transfer device for transferring target objects is provided, processing chambers disposed around the transfer chamber to process the target objects, and load-lock chambers disposed around the transfer chamber to convert an environment around the target objects to an environment inside the transfer chamber, each of the load-lock chambers and its corresponding one of the processing chambers being arranged linearly via the transfer chamber, the method comprising:
(0) loading unprocessed first target objects into the load-lock chambers;
(1) simultaneously transferring one of processed second target objects and one of the unprocessed first target objects into the transfer chamber from one of the processing chambers and one of the load-lock chambers by using the transfer device, said one of the load-lock chambers and said one of the processing chambers being disposed linearly via the transfer chamber;
(2) simultaneously transferring said one of the processed second target objects and said one of the unprocessed target objects into said one of the load-lock chambers and said one of the processing chambers from the transfer chamber by using the transfer device; and
(3) unloading the processed second transfer target objects from the load-lock chambers.

11. The target object transfer method of claim 10, wherein each of the processing chambers is configured to process a plurality of target objects simultaneously.

12. A target object processing apparatus comprising:
a transfer chamber in which a transfer device for transferring a target object is provided;
processing chambers, disposed around the transfer chamber, for processing the target object; and
load-lock chambers, disposed around the transfer chamber, for converting an environment around the target object to an atmosphere in the transfer chamber,
wherein each of the load-lock chambers and its corresponding one of the processing chambers are arranged linearly via the transfer chamber, and
wherein the transfer device is configured to simultaneously transferring target objects between one of the processing chambers and at least one of the load-lock chambers, said one of the load-lock chambers and said one of the processing chambers being disposed linearly via the transfer chamber.

13. The target object processing apparatus of claim 12, wherein each of the processing chambers is configured to process a plurality of target objects simultaneously.

14. The target object transfer method of claim 2, wherein the maximum number of target objects allowed to be simultaneously held by the transfer device is equal to the number of load-dock chambers.
